(19) United States
(12) Patent Application Publication
(10) Pub. No.: US 2023/0395621 A1
(43) Pub. Date: Dec. 7, 2023

(54) IMAGE SENSOR

(71) Applicant: SAMSUNG ELECTRONICS CO., LTD., Suwon-si (KR)

(72) Inventors: Jung Wook LIM, Suwon-si (KR); Seo Joo KIM, Suwon-si (KR); So Eun PARK, Suwon-si (KR); Sung Hyuck CHO, Suwon-si (KR)

(73) Assignee: SAMSUNG ELECTRONICS CO., LTD., Suwon-si (KR)

(21) Appl. No.: 18/119,685

(22) Filed: Mar. 9, 2023

(30) Foreign Application Priority Data
Jun. 7, 2022 (KR) 10-2022-0068937

(51) Int. Cl. H01L 27/146

(52) U.S. Cl. CPC H01L 27/14612; H01L 27/14643; H01L 27/14603

(57) ABSTRACT

An image sensor including a plurality of pixels, wherein each pixel of the plurality of pixels comprises: a first sub-pixel comprising a first photoelectric conversion area, a first floating diffusion area, and a first transfer transistor configured to transfer charges accumulated in the first photoelectric conversion area to the first floating diffusion area; and a second sub-pixel disposed adjacent to the first sub-pixel and comprising a second photoelectric conversion area, a second floating diffusion area and a second transfer transistor configured to transfer charges accumulated in the second photoelectric conversion area to the second floating diffusion area, wherein the first transfer transistor comprises a first transfer gate, wherein the second transfer transistor comprises a second transfer gate, and wherein the second transfer gate comprises a vertical multi-gate

### CROSS-REFERENCE TO RELATED APPLICATION

This application is based on and claims priority under 35 U.S.C. § 119 from Korean Patent Application No. 10-2022-0068937 filed on Jun. 7, 2022 in the Korean Intellectual Property Office, the disclosure of which is incorporated by reference herein in its entirety.

### BACKGROUND

### 1. Field

The present disclosure relates to an image sensor.

### 2. Description of Related Art

An image sensing device may sense an image using an optical sensor. The image sensing device may include an image sensor, for example a complementary metal-oxide semiconductor (CMOS) image sensor. The CMOS image sensor may include a plurality of pixels PX arranged two-dimensionally. Each of the pixels PX may include a photodiode (PD). The photodiode may convert incident light thereto into an electrical signal.

Under development of the computer industry and the communication industry, demand for an image sensor with improved performance is increasing in various fields, such as digital cameras, camcorders, smartphones, game devices, security cameras, medical micro cameras, robots, and vehicles, etc.

### SUMMARY

Provided is an image sensor with improved image quality.

Purposes according to the present disclosure are not limited to the above-mentioned purpose. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized as shown in the claims and combinations thereof.

Additional aspects are set forth in part in the description which follows and, in part, will be apparent from the description, or may be learned by practice of the presented embodiments.

In accordance with an aspect of the disclosure, an image sensor includes a plurality of pixels, wherein each pixel of the plurality of pixels includes: a first sub-pixel including a first photoelectric conversion area, a first floating diffusion area, and a first transfer transistor configured to transfer charges accumulated in the first photoelectric conversion area to the first floating diffusion area; and a second sub-pixel disposed adjacent to the first sub-pixel and including a second photoelectric conversion area, a second floating diffusion area and a second transfer transistor configured to transfer charges accumulated in the second photoelectric conversion area to the second floating diffusion area, wherein the first transfer transistor includes a first transfer gate, wherein the second transfer transistor includes a second transfer gate, and wherein the second transfer gate includes a vertical multi-gate.

In accordance with an aspect of the disclosure, an image sensor includes a substrate; a first photoelectric conversion area disposed in the substrate and having a first width in a horizontal direction; a second photoelectric conversion area disposed in the substrate and having a second width in the horizontal direction, wherein the second width is smaller than the first width; a first floating diffusion area disposed in the substrate and spaced apart from a second floating diffusion area disposed in the substrate; a first transfer transistor at least partially disposed in the substrate or on a face of the substrate, the first transfer transistor being configured to transfer charges accumulated in the first photoelectric conversion area to the first floating diffusion area; and a second transfer transistor at least partially disposed in the substrate or on the face of the substrate, the second transfer transistor being configured to transfer charges accumulated in the second photoelectric conversion area to the second floating diffusion area, wherein the first transfer transistor includes a first transfer gate, wherein the second transfer transistor includes a second transfer gate, and wherein the second transfer gate includes a vertical multi-gate.

In accordance with an aspect of the disclosure, a pixel included in an image sensor includes a first sub-pixel including: a first photoelectric conversion area, a first floating diffusion area, and a first transfer transistor which includes a first transfer gate and is configured to transfer charges accumulated in the first photoelectric conversion area to the first floating diffusion area; and a second sub-pixel disposed adjacent to the first sub-pixel and including: a second photoelectric conversion area, a second floating diffusion area, and a second transfer transistor which includes a second transfer gate, and is configured to transfer charges accumulated in the second photoelectric conversion area to the second floating diffusion area, wherein the second transfer gate includes a vertical multi-gate transistor.

### BRIEF DESCRIPTION OF DRAWINGS

The above and other aspects, features, and advantages of certain embodiments of the present disclosure will be more apparent from the following description taken in conjunction with the accompanying drawings, in which:

FIG. 1 is a block diagram of an image sensing device according to san embodiment.

FIG. 2 is a schematic perspective view showing a stack structure of an image sensor according to an embodiment.

FIG. 3 is a schematic perspective view showing a stack structure of an image sensor according to an embodiment.

FIG. 4 is a block diagram of an image sensor according to an embodiment.

FIG. 5 is a circuit diagram of a pixel of an image sensor according to an embodiment.

FIG. 6 is a schematic layout diagram of a pixel according to an embodiment.

FIG. 7 is a cross-sectional view taken along a line VII-VII′ in FIG. 6, according to an embodiment.

FIG. 8 is a schematic layout diagram of a pixel according to an embodiment.

FIG. 9 is a cross-sectional view taken along a line IX-IX′ of FIG. 8, according to an embodiment.

FIG. 10 is a schematic layout diagram of a pixel according to an embodiment.

FIG. 11 is a cross-sectional view taken along a line XI-XI′ of FIG. 10, according to an embodiment.

FIG. 12 is a schematic layout diagram of a pixel PX according to an embodiment.

FIG. 13 is a cross-sectional view taken along a line XIII-XIII′ of FIG. 12, according to an embodiment.

FIG. 14 and FIG. 15 illustrate circuit diagrams, according to an embodiment.

FIG. 16 is a schematic diagram of a layout of a pixel of a fourth type, and a graph showing an impurity concentration based on a position thereof, according to an embodiment.

FIGS. 17 to 20 are layout diagrams of pixels according to embodiments.

FIGS. 21 to 23 are views of pixel arrangements of an image sensor according to embodiments.

FIG. 24 is a partial layout diagram of a pixel of an image sensor according to an embodiment.

FIG. 25 is a circuit diagram of one pixel from FIG. 24, according to an embodiment.

FIG. 26 is an illustrative timing diagram illustrating an operation of one pixel with a circuit structure of FIG. 25, according to an embodiment.

FIG. 27 is a graph showing a signal-to-noise ratio based on illuminance of a pixel under the pixel operation of FIG. 26, according to an embodiment.

FIG. 28 is a schematic layout diagram of one pixel according to an embodiment.

FIG. 29 is a cross-sectional view of a combination of the first sub-pixel and the second sub-pixel of FIG. 28, according to an embodiment.

FIG. 30 is a schematic diagram showing a relationship between capacitance and electric potential of each of a first photodiode of a first sub-pixel and a second photodiode of a second sub-pixel, according to an embodiment.

FIG. 31 is a schematic layout diagram of one pixel according to an embodiment.

FIG. 32 is a schematic layout diagram of one pixel according to an embodiment.

FIG. 33 is a diagram of a vehicle including an image sensor according to an embodiment.

### DETAILED DESCRIPTION

Hereinafter, embodiments will be described with reference to the accompanying drawings.

As is traditional in the field, embodiments may be described and illustrated in terms of blocks which carry out a described function or functions. These blocks, which may be referred to herein as units, modules, circuits, blocks, drivers, arrays, generators, buffers, processors, or the like, are physically implemented by analog or digital circuits such as logic gates, integrated circuits, microprocessors, microcontrollers, memory circuits, passive electronic components, active electronic components, optical components, hardwired circuits, or the like, and in embodiments may be driven by firmware. The circuits may, for example, be embodied in one or more semiconductor chips, or on substrate supports such as printed circuit boards and the like. The circuits included in a block may be implemented by dedicated hardware, or by a processor (e.g., one or more programmed microprocessors and associated circuitry), or by a combination of dedicated hardware to perform some functions of the block and a processor to perform other functions of the block. Each block of embodiments may be physically separated into two or more interacting and discrete blocks without departing from the scope of the disclosure. Likewise, the blocks of embodiments may be physically combined into more complex blocks without departing from the scope of the disclosure

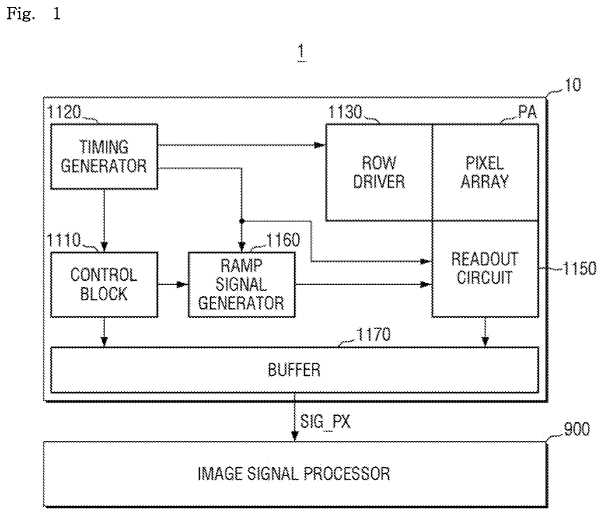

FIG. 1 is a block diagram of an image sensing device according to some embodiments.

Referring to FIG. 1, an image sensing device 1 may include an image sensor 10 and an image signal processor 900.

The image sensor 10 may sense an image of a sensing target using light, and may generate a pixel signal SIG_PX based on the sensed image. The generated pixel signal SIG_PX may be, for example, a digital signal. However, embodiments are not limited thereto. Further, the pixel signal SIG_PX may include specific signal voltage or reset voltage, etc. The pixel signal SIG_PX may be provided to and processed by the image signal processor 900.

The image sensor 10 may include a control block 1110, which may be for example a control register block, a timing generator 1120, a row driver 1130, a pixel array PA, a readout circuit 1150, a ramp signal generator 1160, and a buffer 1170.

The control block 1110 may control all operations of the image sensor 10. The control block 1110 may send an operation control signal directly to the timing generator 1120, the ramp signal generator 1160 and the buffer 1170.

The timing generator 1120 may generate an operation timing reference signal as a reference for an operation timing of each of the various components of the image sensor 10. The operation timing reference signal generated from the timing generator 1120 may be transmitted to the row driver 1130, the readout circuit 1150, the ramp signal generator 1160, and the like.

The ramp signal generator 1160 may generate and transmit a ramp signal to be used in the readout circuit 1150. The readout circuit 1150 may include a correlated double sampler (CDS), a comparator, etc. The ramp signal generator 1160 may generate and transmit the ramp signal to be used in the CDS, the comparator, and the like.

The buffer 1170 may temporarily store therein the pixel signal SIG_PX to be provided to an external component, and may transmit the pixel signal SIG_PX to an external memory or an external device. The buffer 1170 may include a memory such as dynamic random access memory (DRAM) or static random access memory (SRAM).

The pixel array PA may sense an external image. The pixel array PA may include a plurality of pixels PX (or a unit pixel PX). The row driver 1130 may selectively activate a row of the pixel array PA.

The readout circuit 1150 may sample the pixel PX signal provided from the pixel array PA, may compare the sampled signal with the ramp signal, and may convert an analog image signal or data into a digital image signal or data based on the comparison result.

The image signal processor 900 may receive the pixel signal SIG_PX output from the buffer 1170 of the image sensor 10 and may process the received pixel signal SIG_PX for display thereof. The image signal processor 900 may be physically spaced from the image sensor 10. For example, the image sensor 10 may be mounted into a first chip while the image signal processor 900 may be mounted into a second chip. The image signal processor 900 and the image sensor 10 may communicate with each other through a predefined interface. However, embodiments are not limited thereto, and the image sensor 10 and the image signal processor 900 may be implemented into one package, for example, a multi-chip package (MCP).

As described above, the image sensor may be implemented using a single chip. For example, all the functional blocks as described above may be implemented in one chip. However, embodiments are not limited thereto, and the functional blocks may be distributed across a plurality of chips. When the image sensor includes as a plurality of chips, the chips may be stacked. Hereinafter, an example in which the image sensor includes the stack of the chips will be described.

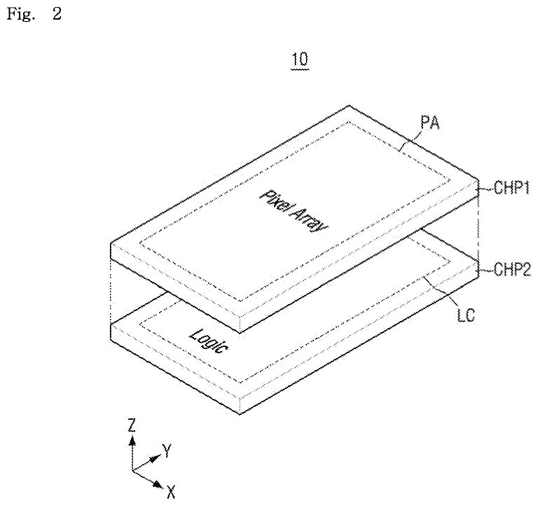

FIG. 2 is a schematic perspective view showing a stack structure of an image sensor according to an embodiment. In FIG. 2, a first direction X, a second direction Y, and a third direction Z are illustrated. The first direction X, the second direction Y and the third direction Z may intersect each other. For example, the first direction X, the second direction Y, and the third direction Z may intersect each other perpendicularly. Each of the first direction X and the second direction Y may be a horizontal direction, and the third direction Z may be a vertical direction. For example, the third direction Z may be a thickness direction and/or a depth direction of the device.

Referring to FIG. 2, the image sensor 10 may include a stack which includes an upper chip CHP1 and a lower chip CHP2. The upper chip CHP1 may include the pixel array PA. The lower chip CHP2 may include an analog area and a logic area LC including the readout circuit 1150. The lower chip CHP2 may be disposed below the upper chip CHP1, for example lower than the upper chip CHP1 in the third direction Z, and may be electrically connected to the upper chip CHP1. The lower chip CHP2 may receive the pixel PX signal from the upper chip CHP1. The logic area LC may receive the corresponding pixel PX signal.

Logic elements may be disposed in the logic area LC of the lower chip CHP2. The logic elements may include circuits for processing the pixel PX signal from the pixels PX. For example, the logic elements may include the control block 1110, the timing generator 1120, the row driver 1130, the readout circuit 1150, the ramp signal generator 1160, and the like.

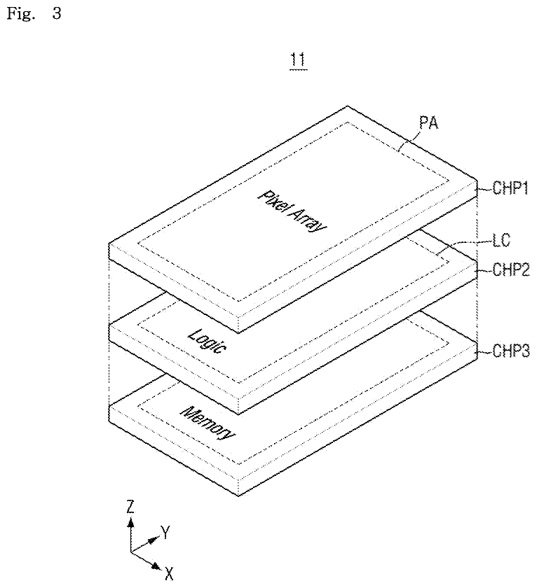

FIG. 3 is a schematic perspective view showing a stack structure of an image sensor according to another embodiment. For example, the image sensor 11 illustrated in FIG. 3 may differ from the image sensor 10 illustrated in FIG. 2 in that an image sensor 11 of FIG. 3 may further include a memory chip CHP3.

Specifically, as shown in FIG. 3, the image sensor 11 may include the upper chip CHP1, the lower chip CHP2, and the memory chip CHP3. The upper chip CHP1, the lower chip CHP2, and the memory chip CHP3 may be sequentially stacked along the third direction Z. The memory chip CHP3 may be disposed below the lower chip CHP2, for example lower than the lower chip CHP2 in the third direction Z. The memory chip CHP3 may include a memory device. For example, the memory chip CHP3 may include a volatile memory device such as DRAM or SRAM. The memory chip CHP3 may receive a signal from the upper chip CHP1 and the lower chip CHP2 and may process the signal using the memory device. The image sensor 11 including the memory chip CHP3 may act as a 3-stack image sensor.

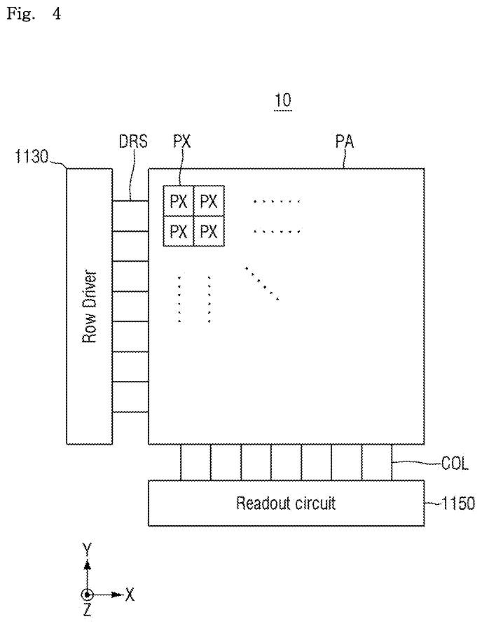

Hereinafter, the pixel array PA of the image sensor will be described in more detail. FIG. 4 is a block diagram of an image sensor according to an embodiment.

Referring to FIG. 4, the pixel array PA may include a plurality of pixels PX. The pixel PX may be or include a basic sensing unit which may receive light and output an image corresponding to one pixel PX. Each pixel PX may include a photoelectric converter.

The plurality of pixels PX may be arranged in a two-dimensional matrix having a plurality of rows and a plurality of columns. For convenience of description, a row may refer to an array extending in the first direction X and a column refers to an array extending in the second direction Y in FIG. 4. However, embodiments are not limited thereto. A row may refer to an array extending in the second direction Y and a column may refer to an array extending in the first direction X in FIG. 4. Although a case where the rows and the columns intersect each other in a rectangular matrix manner is illustrated in the drawing, an arrangement shape of the pixels PX may be variously modified. For example, the row or the column may extend in a zigzag manner rather than a straight line, or pixels PXs disposed in adjacent rows/columns may be arranged in a staggered manner.

A plurality of drive signal lines DRS are connected to the row driver 1130. The plurality of drive signal lines DRS may extend along a row extension direction, that is, the first direction X. The plurality of drive signal lines DRS may extend, in the first direction X, across an active area of the pixel array PA as an effective area in which the pixels PX are disposed. The plurality of drive signal lines DRS may transmit a drive signal provided from the row driver to the pixels PX. The drive signal may include, for example, a select signal, a reset signal, a transfer signal, and the like.

In an embodiment, the pixels PX arranged in the same row may be connected to the same drive signal line DRS. In embodiments, the pixels PX disposed in different rows may be connected to different drive signal lines DRS. However, an embodiment is not limited thereto, and the pixels PX disposed in the same row may be connected to different drive signal lines DRS, or the pixels PX disposed in two or more different rows may be connected to the same drive signal line DRS.

A plurality of output signal lines COL may be connected to the readout circuit 1150. The plurality of output signal lines COL may extend along a column extension direction, that is, the second direction Y. The plurality of output signal lines COL may extend across the active area of the pixel array PA in the second direction Y. The plurality of output signal lines COL may transmit an output signal provided from the pixels PX to the readout circuit 1150.

In an embodiment, the pixels PX disposed in the same column may be connected to the same output signal line COL. In embodiments, the pixels PX disposed in different columns may be connected to different output signal lines COL. However, an embodiment is not limited thereto, and pixels PX disposed in the same column may be connected to different output signal lines COL, or pixels PX disposed in two or more different columns may be connected to the same output signal line COL.

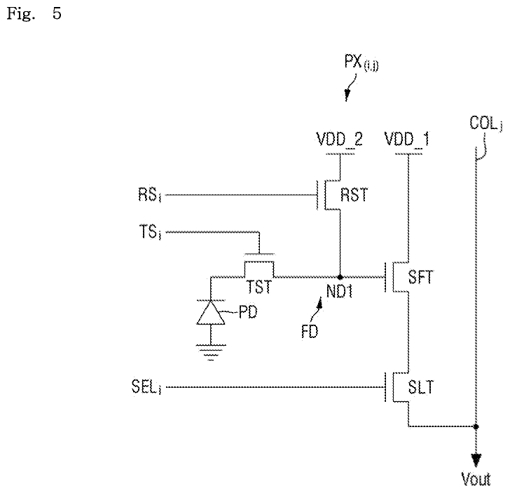

FIG. 5 is a circuit diagram of a pixel of an image sensor according to an embodiment. FIG. 5 illustrates a circuit diagram of a pixel PX(i,j) disposed at an intersection of an i-th row and a j-th column.

Referring to FIG. 5, a pixel PX(i,j) circuit may include a photodiode PD, a floating diffusion area FD, and a plurality of transistors. Although the drawing illustrates a case in which each of the plurality of transistors is a NMOS transistor, embodiments are not limited thereto. Each of the plurality of transistors may be implemented using a PMOS transistor. In embodiments, each of some thereof may be implemented using a NMOS transistor, while each of the other thereof may be implemented using a PMOS transistor.

The plurality of transistors may include, but is not limited to, a transfer transistor TST, a source follower transistor SFT, a select transistor SLT, and a reset transistor RST.

The photodiode PD may act as a photoelectric conversion element, and may generate electric charges from light incident onto the pixel PX from an outside. The photodiode PD may generate electric charges in proportion to an amount of the incident light. Some or all of the generated charges may accumulate in the photodiode PD.

The floating diffusion area FD denoted as a first node ND1 may receive the charges generated from the photodiode PD through the transfer transistor TST. Because the floating diffusion area FD may have parasitic capacitance, charges may be accumulated therein. The floating diffusion area FD may play a role in converting the electric charges into voltage.

The transfer transistor TST may be disposed between the photodiode PD and the floating diffusion area FD. One end of the transfer transistor TST may be connected to the photodiode PD, and the other end thereof may be connected to the floating diffusion area FD. A gate of the transfer transistor TST may be connected to a transfer line of a corresponding row. The transfer transistor TST may transfer the charges accumulated in the photodiode PD to the floating diffusion area FD in response to a transfer signal TSi input from the transfer line.

The source follower transistor SFT may be disposed between and connected to a first power voltage line providing a first power voltage VDD_1 and an output signal line COLj. A gate of the source follower transistor SFT may be connected to the floating diffusion area FD. An output value of the source follower transistor SFT may be controlled based on the charges applied to the floating diffusion area FD connected to the gate thereof.

The select transistor SLT may be disposed between the source follower transistor SFT and the output signal line COLⱼ. A gate of the select transistor SLT may be connected to a select line of a corresponding row. The select transistor SLT may electrically connect the source follower transistor SFT and the output signal line COLj to each other in response to a select signal SELi input thereto.

The reset transistor RST may be configured to reset the floating diffusion area FD. The reset transistor RST may be disposed between a second power voltage line providing a second power voltage VDD_2 and the floating diffusion area FD.

A gate of the reset transistor RST may be connected to a reset line of a corresponding row. The reset transistor RST may connect the floating diffusion area FD to a second power voltage terminal based on a reset signal RSi input thereto to reset the floating diffusion area FD to the second power voltage VDD_2.

The above-described second power voltage VDD_2 may be different from or equal to the first power voltage VDD_1. Each of the first power voltage VDD_1 and the second power voltage VDD_2 may be a reference voltage, for example a direct current (DC) voltage, that does not swing. However, embodiments are not limited thereto.

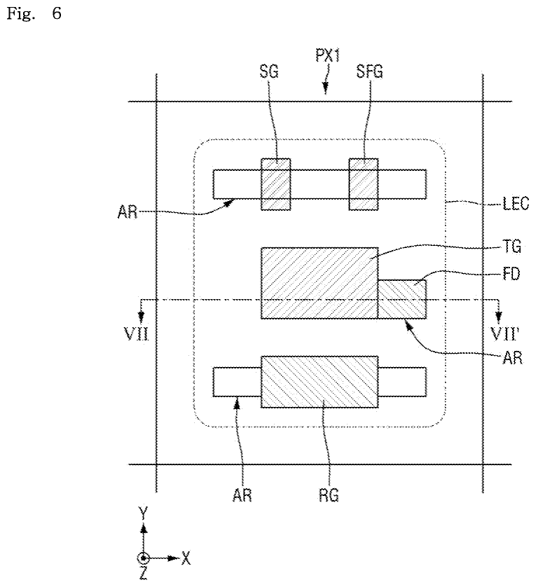

Although FIG. 6 illustrates a case in which the second power voltage line and the first power voltage line are implemented using separate voltage lines, the second power voltage line and the first power voltage line may be respectively implemented using lines branched from one voltage line. The first power voltage line and the second power voltage line may provide the same power voltage regardless of a column of the pixel PX. However, embodiments are not limited thereto.

Each of the pixels PX of the image sensor may have a circuit structure substantially the same as or similar to that shown in FIG. 5. However, each of at least some pixels PX of the image sensor according to some embodiments may have a different layout or cross-sectional structure for implementing the same or similar circuit from that of each of the other pixels PX. The layout and cross-sectional structure of each of the pixels PX may be variously modified. Specifically, different types of pixels PX may be defined based on different layouts or cross-sectional structures of the transfer transistors TST. For example, the pixels PX may be classified into different types of pixels PX based on gate types of the transfer transistors TST of the pixels PX.

A gate type may be classified as a horizontal gate or a vertical gate based on one classification criterion. This criterion may relate to whether the gate is embedded in a substrate.

The gate type may be classified as a single gate or a multi-gate based on another classification criterion. This criterion may relate to whether the gate includes a plurality of sub-gates.

The gate type may be classified as a straight gate, a curved gate, or a closed curved gate based on still yet another classification criterion. This criterion may relate to a planar shape of the gate.

In embodiments, a combination of at least two criteria among the above criteria may be applied to determine a gate type. For example, the gate types may be classified as a horizontal straight single gate, a horizontal double gate, a horizontal multi-gate, a horizontal closed curved gate, a vertical straight single gate, a vertical double gate, a vertical multi-gate, a vertical closed curved gate, etc. A specific gate type is not limited to the examples as listed above.

A specific gate type classified based on the combination of at least two criteria may be referred to using one or more of the at least two criteria, respectively. For example, the vertical multi-gate may also be referred to as a vertical gate and may also be referred to as a multi-gate.

Hereinafter, the pixels PX may be referred to as different names based on gate types of gates included in the pixels PX, respectively. For example, a pixel PX with a transfer transistor TST with a horizontal straight single gate may be referred as a pixel of a first type. A pixel PX with a horizontal double/multi/closed curved gate may be referred as a pixel of a second type. A pixel PX with a vertical single gate may be referred as a pixel of a third type. A pixel PX with a vertical double/multi/closed curved gate may be referred to as a pixel of a fourth type. However, the terms such as the first, the second, etc. used to distinguish the types of the pixels PX from each other may vary depending on embodiments.

Hereinafter, each of various types of pixels PX that the image sensor 10 may include will be described.

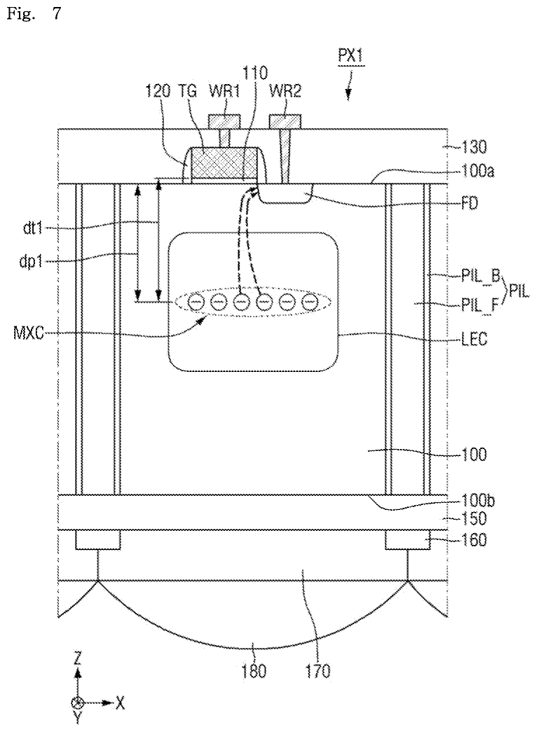

FIG. 6 is a schematic layout diagram of a pixel according to an embodiment. FIG. 7 is a cross-sectional view taken along a line VII-VII′ in FIG. 6. FIG. 6 and FIG. 7 illustrate a case where a pixel PX1 is implemented using a pixel of the first type in which a transfer transistor TST includes a horizontal single gate.

Referring to FIG. 6, a photoelectric conversion area LEC is disposed in one pixel PX1 area. In the illustrated embodiment, one photoelectric conversion area LEC is disposed in one pixel PX1 area. However, embodiments are not limited thereto. Two or more photoelectric conversion areas LEC may be disposed in one pixel PX1 area. The photoelectric conversion area LEC may correspond to the photodiode PD in FIG. 5. The photoelectric conversion area LEC may generate electric charges in proportion to an amount of light incident thereto from an outside.

Further, one pixel PX1 area may include a gate of a transfer transistor TST, which may be referred to as a transfer gate TG, a gate of a source follower transistor SFT, which may be referred to as a source follower gate SFG, a of a select transistor SLT, which may be referred to as a select gate SG, and a gate (of a reset transistor RST, which may be referred to as reset gate RG. In FIG. 6, it is illustrated that the transfer gate TG is disposed in a center of the pixel PX1 area, the select gate SG and the source follower gate SFG are disposed at one side (which may correspond to an upper side in FIG. 6) in the second direction Y around the transfer gate TG and arranged side by side in the first direction X, and the reset gate RG is disposed at the other side (which may correspond to a lower side in FIG. 6) in the second direction Y around the transfer gate TG. However, embodiments are not limited thereto. A relative positional relationship thereof may be variously modified. Further, in FIG. 6, it is illustrated that a planar shape of each of the gates is a rectangle or a square is illustrated. However, embodiments are not limited thereto. The planar shape thereof may be variously modified.

A transistor active area AR may be arranged around each of the gates. The transistor active area AR may include an impurity area, and the impurity area may be used as a source/drain area and/or the floating diffusion area FD of the transistor. In some embodiments, the source/drain area of the transistor may include a first source/drain area and a second source/drain area. The first source/drain area and the second source/drain area of the same transistor may respectively act as a source area and a drain area or vice versa based on a type of a voltage applied thereto. At a time point when the applied voltage is maintained to be constant, one of the first source/drain area and the second source drain area of the same transistor may act as the source area, while the other thereof may act as the drain area.

One or more transistor active areas AR may be disposed in one pixel PX1. When a plurality of transistor active areas AR are present therein, the transistor active areas AR may be spaced from each other. FIG. 6 illlustrates a case in which three transistor active areas AR are arranged.

As shown in FIG. 6, a floating diffusion area FD may be disposed on one side in the direction X of the transfer gate TG.

Further, a first source/drain area of the reset transistor RST may be disposed on one side in the direction X of the reset gate RG, while a second source/drain area of the reset transistor RST may be disposed on the other side in the direction X of the reset gate RG.

Further, a first source/drain area of the select transistor SLT may be disposed on one side in the direction X of the select gate SG, while a second source/drain area thereof may be disposed on the other side in the direction X of the select transistor SLT. Further, a first source/drain area of the source follower transistor SFT may be disposed on one side in the direction X of the source follower gate SFG, while a second source/drain area thereof may be disposed on the other side in the direction X of the source follower gate SFG. The second source/drain area of the select transistor SLT and the first source/drain area of the source follower transistor SFT may be connected to the same node in a circuit diagram, and may be physically integrally formed.

Referring to FIG. 6 and FIG. 7, the image sensor or the pixel PX1 included therein may include the substrate 100, the photoelectric conversion area LEC, an active area AR1, a pixel isolation film PIL, the gate TG, a gate insulating film 110 and a gate spacer 120. In a cross-sectional view of FIG. 7, the floating diffusion area FD acting as the transistor active area AR is shown, and the transfer gate TG acting as the gate is shown.

The substrate 100 may be implemented using a semiconductor substrate. For example, the substrate 100 may be made of bulk silicon or SOI (silicon-on-insulator). The substrate 100 may implemented using a silicon substrate, or may include a material other than silicon, for example, silicon germanium, indium antimonide, lead telluride compound, indium arsenide, indium phosphide, gallium arsenide or gallium antimonide. The substrate 100 may include a base substrate and an epitaxial layer formed on the base substrate.

The substrate 100 may include a first face 100a and a second face 100b opposite to each other. In following embodiments, in some cases, the first face 100a may be referred to as a front side of the substrate 100, and the second face 100b may be referred to as a back side of the substrate 100. The second face 100b of the substrate 100 may be a light receiving face on which light is incident. That is, the image sensor according to some embodiments may be a backside-illumination (BSI) image sensor.

In some embodiments, the substrate 100 may have a first conductivity type. For example, the substrate 100 may contain p-type impurities (e.g., boron (B)). In following embodiments, an example in which the first conductivity type is a p-type is described. However, this is only an example. In another example, the first conductivity type may be an n-type.

The photoelectric conversion area LEC may be disposed within the substrate 100. The photoelectric conversion area LEC may be disposed in a space between the first face 100a and the second face 100b. The photoelectric conversion area LEC may be disposed to be spaced apart, by a predetermined distance, from each of the first face 100a and the second face 100b. The distance between the photoelectric conversion area LEC and the first face 100a may be smaller than the distance between the photoelectric conversion area LEC and the second face 100b. However, embodiments are not limited thereto.

In a plan view, the photoelectric conversion area LEC may overlap with at least the transfer gate TG and the floating diffusion area FD. Furthermore, the photoelectric conversion area LEC may overlap with the reset gate RG, the source follower gate SFG, the select gate SG and the transistor active area AR connected thereto in the plan view. However, embodiments are not limited thereto, and a planar arrangement of the photoelectric conversion area LEC may be variously modified.

The photoelectric conversion area LEC may have a second conductivity type different from the first conductivity type. In following embodiments, an example in which the second conductivity type is an n-type is described. However, this is only an example. In another example, the second conductivity type may be a p-type. The photoelectric conversion area LEC may be formed, for example, by implanting n-type impurities, for example, phosphorus (P) or arsenic (As) into the substrate 100 of the p-type conductivity.

The impurities injected into the photoelectric conversion area LEC may have a concentration varying based on areas. The ion-implanted impurities may be diffused within the substrate 100. The impurities diffuse throughout an entire volume of the photoelectric conversion area LEC to have a concentration varying based on areas. A detailed description of an thereof is provided below.

The floating diffusion area FD may be positioned inside the substrate 100. The floating diffusion area FD may be disposed in the active area AR. The floating diffusion area FD may be disposed adjacent to the first face 100a of the substrate 100. In a plan view, the floating diffusion area FD may overlap the photoelectric conversion area LEC. The floating diffusion area FD may be spaced from the photoelectric conversion area LEC in the third direction Z, for example in a thickness direction of the pixel.

The floating diffusion area FD may have the second conductivity type. For example, the floating diffusion area FD may be implemented using a first impurity area formed by ion implantation of n-type impurities into the substrate 100 of the p-type conductivity.

In some embodiments, the floating diffusion area FD may have the second conductivity type and have a higher impurity concentration than that of the photoelectric conversion area LEC. For example, the floating diffusion area FD may be formed by ion implantation of a high concentration of n-type impurities (n⁺) in the substrate 100 of the p-type conductivity.

The pixel isolation film PIL may be further positioned inside the substrate 100. The pixel isolation film PIL may isolate neighboring pixels PX1 from each other. The pixel isolation film PIL may prevent drift of charges between the adjacent pixels PX1.

The pixel isolation film PIL may be disposed at a boundary area of the pixel PX1 in plan view. The pixel isolation film PIL may continuously extend along the boundary of the pixel PX1 in a plan view. In a plan view, the pixel isolation film PIL may have a grid shape.

In one embodiment, the pixel isolation film PIL may extend from the first face 100a of the substrate 100 to the second face 100b thereof. One end in an extension direction of the pixel isolation film PIL may be disposed on the first face 100a of the substrate 100 while the other end in the extension direction thereof may be disposed on the second face 100b of the substrate 100. In other words, the pixel isolation film PIL may extend through the substrate 100 in the third direction Z. However, embodiments are not limited thereto, and one end or the other end of the pixel isolation film PIL may be positioned inside the substrate 100 to form a trench shape.

The pixel isolation film PIL may be formed by removing a portion of a constituent material of the substrate 100 and then filling a space obtained by the removal thereof with an isolation film material.

In an embodiment, the pixel isolation film PIL may include a barrier layer PIL_B and a filling layer PIL_F.

The barrier layer PIL_B may constitute a sidewall of the pixel isolation film PIL. The barrier layer PIL_B may include, but is not limited to, a high-k insulating material. The barrier layer PIL_B may define a predetermined space, and the filling layer PIL_F may be disposed in the space. The filling layer PIL_F may include a material having excellent gap-fill performance, for example, polysilicon (poly-Si). However, embodiments are not limited thereto.

The transfer gate TG may be disposed on the first face 100a of the substrate 100. In the illustrated example, the transfer gate TG has a horizontal single gate structure. One side face of the transfer gate TG may be aligned with or overlap one edge of the floating diffusion area FD.

The transfer gate TG may include, for example, at least one of impurity-doped polysilicon (poly Si), metal silicide such as cobalt silicide, metal nitride such as titanium nitride, or metal such as tungsten, copper and aluminum. However, embodiments are not limited thereto.

The gate insulating film 110 may be disposed on the first face 100a of the substrate 100. The gate insulating film 110 may be disposed between the transfer gate TG and the substrate 100. The gate insulating film 110 may include, for example, at least one of silicon nitride (SiN), silicon oxynitride (SiON), silicon carbonitride (SiCN), a low-k material having a lower dielectric constant than that of silicon oxide, or a high-k material having a higher dielectric constant than that of silicon oxide. However, embodiments are not limited thereto.

The gate spacer 120 may be disposed on a side face of the transfer gate TG. The gate spacer 120 may include at least one of silicon nitride, silicon oxynitride, silicon carbonitride (SiCN), silicon oxycarbonitride (SiOCN), silicon boron nitride (SiBN), silicon oxyboron nitride (SiOBN), silicon oxycarbide (SiOC), or combinations thereof. In embodiments, the gate spacer 120 may be omitted.

In embodiments, each of the reset transistor RST, the source follower transistor SFT, and the select transistor SLT may include the gate insulating film 110 and the gate spacer 120 as illustrated in FIG. 7, similarly to the transfer transistor TST. Further, each of the reset transistor RST, the source follower transistor SFT, and the select transistor SLT may include a first source/drain area on one side of each of the reset gate RG, the source follower gate SFG and the select gate SG, and a second source/drain area on the other side thereof.

An interlayer insulating film 130 may be disposed on the transfer gate TG. The interlayer insulating film 130 may include, for example, at least one of silicon oxide, silicon nitride, silicon oxynitride, a low-k material, or combinations thereof.

A wire layer WR1 and WR2 may be disposed on the interlayer insulating film 130. The wire layer WR1 and WR2 may include, for example, aluminum (Al), copper (Cu), tungsten (W), cobalt (Co), ruthenium (Ru), and the like. However, embodiments are not limited thereto. The wire layer may include a plurality of wires WR1 and WR2, and at least some of the wires WR1 and WR2 may be connected to the transfer gate TG and the floating diffusion area FD using a via extending through the interlayer insulating film 130.

In some embodiments, the image sensor 10 may further include a color filter 170, a micro lens 180, a grid pattern 160, and a passivation layer 150 disposed on the second face 100b of the substrate 100.

Specifically, the passivation layer 150 may be disposed on the second face 100b of the substrate. The passivation layer 150 may include, for example, a high-k insulating material. Further, the passivation layer 150 may include an amorphous crystal structure.

Although FIG. 7 illustrates a case in which the passivation layer 150 includes only one layer, embodiments are not limited thereto. In some other embodiments, the passivation layer 150 may further include a planarization layer and/or an anti-reflection layer. In this case, the planarization layer may include, for example, at least one of a silicon oxide-based material, a silicon nitride-based material, a resin, or combinations thereof. The anti-reflection layer may include a high-k material, for example, hafnium oxide (HfO₂). However, the technical spirit of embodiments are not limited thereto.

The color filter 170 may be disposed on the passivation layer 150. Each color filter 170 may correspond to each unit pixel PX1. For example, the color filters 170 may be arranged two-dimensionally (for example, in a matrix manner) in a plane defined by the first direction X and the second direction Y.

The color filter 170 may include a red, green, or blue color filter disposed in each pixel PX1. Further, the color filter 170 may include a yellow filter, a magenta filter, and a cyan filter, and may further include a white filter.

The grid pattern 160 may be formed in a grid shape and on the second face 100b of the interlayer insulating film 130, which may be referred to as a second substrate, and may be disposed to surround each pixel PX1. For example, the grid pattern 160 may be disposed between the color filters 170 and on the passivation layer 150. The grid pattern 160 may reflect incident light thereto therefrom in an oblique manner to provide a larger amount of the incident light to the photoelectric conversion area LEC.

The micro lens 180 may be disposed on the color filter 170. Each micro lens 180 may correspond to each pixel PX1. In an embodiment, one micro lens 180 may be disposed on one color filter 170.

The micro lens 180 may be disposed to cover the photoelectric conversion area LEC. The micro lens 180 may have a convex face to condense the incident light to the photoelectric conversion area LEC. The micro lens 180 may include, but is not limited to, a photoresist material or a thermosetting resin.

Further examples of the pixel of the image sensor will be described. In following embodiments, the reference numerals of the components as already described above are equally allocated to the same components as those as already described above, and duplicate descriptions thereof are omitted or simplified.

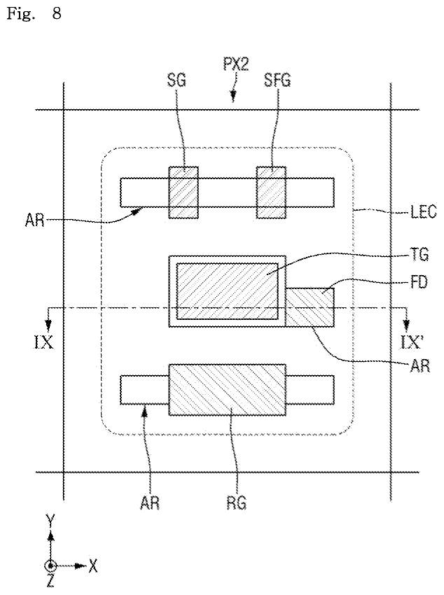

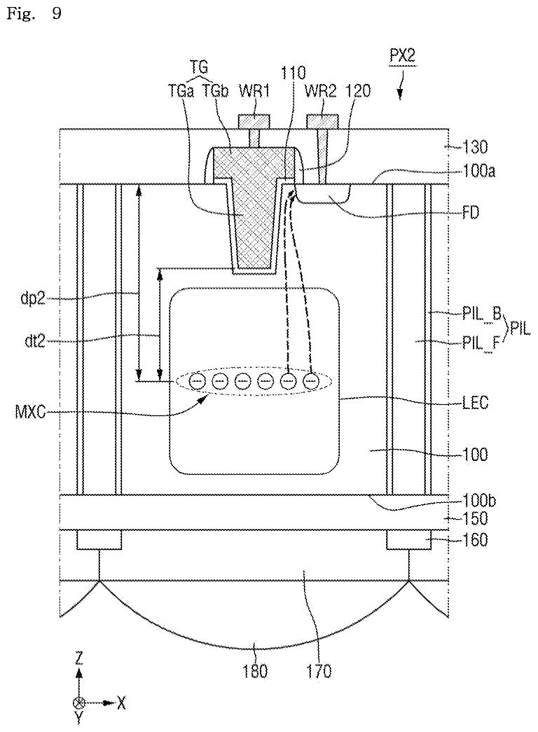

FIG. 8 is a schematic layout diagram of a pixel according to another embodiment. FIG. 9 is a cross-sectional view taken along a line IX-IX′ of FIG. 8. A pixel PX2 illustrated in FIG. 8 and FIG. 9 may differ from the pixel PX1 in FIG. 6 and FIG. 7 in that the transfer transistor TST of the pixel PX1 includes the horizontal single gate, while the transfer transistor TST of the pixel PX2 includes a vertical single gate, that is, the pixel PX2 may be of the second type.

Referring to FIG. 8 and FIG. 9, the transfer gate TG may be at least partially embedded in the substrate 100. The transfer gate TG may include a first portion TGa positioned inside the substrate 100 and a second portion TGb disposed above the first face 100a of the substrate 100. A boundary between the first portion TGa and the second portion TGb may be generally defined as the first face 100a of the substrate 100 or an extension face from the first face 100a of the substrate 100. The first portion TGa and the second portion TGb of the transfer gate TG may be integrally formed with each other or monolithic so that an interface therebetween is not formed.

A maximum width in a horizontal direction (e.g., in the first direction X) of the second portion TGb of the transfer gate TG may be greater than a maximum width in the horizontal direction (e.g., in the first direction X) of the first portion TGa thereof. A side face of the second portion TGb of the transfer gate TG may protrude outwardly beyond a side face of the first portion TGa, and a protruding portion thereof may overlap the first face 100a of the substrate 100 in a thickness direction, that is, the third direction Z.

The substrate 100 may have a trench defined therein that may accommodate therein the first portion TGa of the transfer gate TG. The first portion TGa of the transfer gate TG may fill the trench. The gate insulating film 110 may be formed not only on a portion of the first face 100a of the substrate 100 but also on a sidewall and a bottom face of the trench. Accordingly, the gate insulating film 110 may be interposed between the substrate 100 and the transfer gate TG (including both the first portion TGa and the second portion TGb).

The first portion TGa of the transfer gate TG may extend from the first face 100a toward the second face 100b. A width in the horizontal direction of the first portion TGa of the transfer gate TG may decrease as the first portion extends toward the second face 100b. An end of the first portion TGa of the transfer gate TG may be spaced apart from the floating diffusion area FD.

When the transfer gate TG has a vertical gate shape at least partially buried in the substrate 100, a distance between the transfer gate TG and the photoelectric conversion area LEC may be reduced. A distance between the transfer gate TG and the photoelectric conversion area LEC is related to transfer efficiency of the transfer transistor TST. A detailed description of an example thereof is provided below with reference to FIG. 7 and FIG. 9.

Referring to FIGS. 7 and 9, as described above, the photoelectric conversion area LEC may be formed under an ion implantation process. A relative position of the photoelectric conversion area LEC between the first face 100a and the second face 100b of the substrate 100 may vary depending on a process condition of the ion implantation process.

For example, first, a doping depth of impurity ions in the ion implantation process may be set. The doping depths in all of the pixels PX1 and PX2 may be set to be equal to each other, or may be set to be different from each other.

Initially implanted impurity ions may exist at a high concentration in a small space of the set doping depth in the substrate 100. The implanted impurity ions may diffuse from an implanted site toward an adjacent area thereto with a low concentration. A diffusion direction of the impurity ions may be all directions in three dimensions unless a specific constraint is present. As the diffusion proceeds, a volume of the photoelectric conversion area LEC may increase, while an impurity ion concentration per unit volume may decrease.

The diffusion of the impurity ions may not lead to distribution at a uniform concentration or density of the impurity ions in all diffused areas. For example, in some embodiments, the concentration of the impurity ions at a position may decrease as a distance between the position and the initially implanted area increases. However, embodiments are not limited thereto. For example, the impurity ion concentration at a position is not necessarily inversely proportional to a distance between the position and the initially implanted area. Distribution of the impurity concentration in the photoelectric conversion area LEC where diffusion has been completed may be variously changed depending on a diffusion condition, a difference between constituent materials of different areas of the substrate 100, presence or absence of other types of impurities, or a geometric shape of the substrate 100, etc.

A maximum concentration area MXC having the highest impurity ion concentration in each of the pixels PX1 and PX2 may be an area corresponding to the set doping depth. However, as described above, the maximum concentration area MXC may vary depending on the impurity ion diffusion process condition and the geometric shape of the substrate.

A relative position of the maximum concentration area MXC having the maximum impurity ion concentration in the photoelectric conversion area LEC may vary depending on the pixels PX1 and PX2. For example, in one pixel PX1 in the image sensor, the maximum impurity concentration area MXC may be disposed at a first depth dp1, which may be for example a first distance from the first face 100a of the substrate 100 as shown in FIG. 7. In another pixel PX2, the maximum impurity concentration area MXC may be disposed at a second depth dp2, which may be for example a second distance from the first face 100a of the substrate 100 as shown in FIG. 9. In embodiments, the second depth dp2 may be larger than the first depth dp1. A configuration in which the maximum impurity concentration areas MXC are positioned at the different depths, respectively in the pixels PX1 and PX2 may be obtained or achieved by, for example, intentionally setting impurity ion doping depths of the different pixels PX1 and PX2 or different pixel groups to be different from each other. However, embodiments are not limited thereto. Depths at which the maximum ion concentration areas are positioned in the different pixels may be different from each other due to other intentional settings or unintentional conditions.

The impurity concentration may be proportional to electric potential applied to the photoelectric conversion area LEC. For example, an area having a high impurity concentration may have a relatively high electric potential, and an area having a low impurity concentration may have a relatively low electric potential. As the electric potential of the area is higher, the area may generate and/or accumulate therein a larger amount of charges. Therefore, the maximum impurity concentration area MXC in the photoelectric conversion area LEC may be a maximum charge generation/accumulation area.

As described above, the charges generated in the photoelectric conversion area LEC may be transferred to the floating diffusion area FD through the transfer transistor TST. A distance between the charge to be transferred and the transfer gate TG may be one of factors determining transfer efficiency of the transfer transistor TST. In general, the larger the distance between the charge and the gate, the lower the transfer efficiency may be. From this point of view, there is a possibility that the substrate 100 of FIG. 9 which has a relatively deeper maximum impurity concentration area MXC (i.e., maximum charge generation/accumulation area) may have lower transfer efficiency than that of the substrate 100 of FIG. 7.

In the pixel PX2 as illustrated in FIG. 9, the transfer gate TG may be implemented using a vertical gate, and thus, a second spacing dt2 between the transfer gate TG and the maximum impurity concentration area MXC may be reduced. A difference between the second depth dp2 and the second spacing dt2 in FIG. 9 may be larger than a difference between the first depth dp1 and a first spacing dt1 between the transfer gate TG and the maximum impurity concentration area MXC in FIG. 7. Thus, a difference between a transfer efficiency of the transfer transistor TST of FIG. 9 and a transfer efficiency of the transfer transistor TST of FIG. 7 may be reduced.

In the pixel PX2 in FIG. 9, the second spacing dt2 may be adjusted based on a depth at which the vertical gate is embedded in the substrate 100. In an embodiment, adjusting the depth at which the vertical gate is embedded in the substrate 100 may allow the transfer efficiency of the transfer transistor TST of the pixel PX2 in FIG. 9 and the transfer efficiency of the transfer transistor TST of the pixel PX1 in FIG. 7 to be equal to each other.

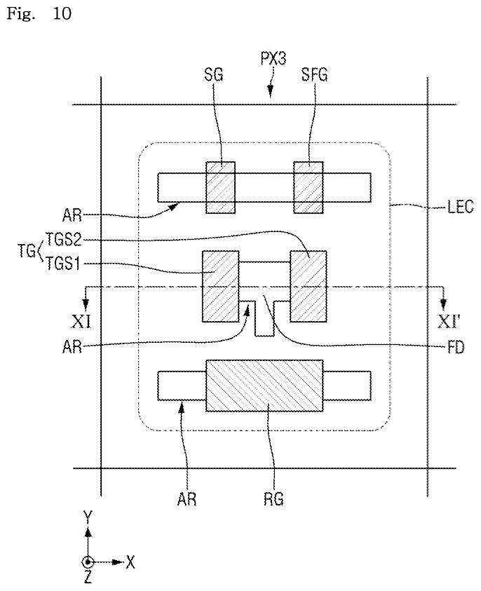

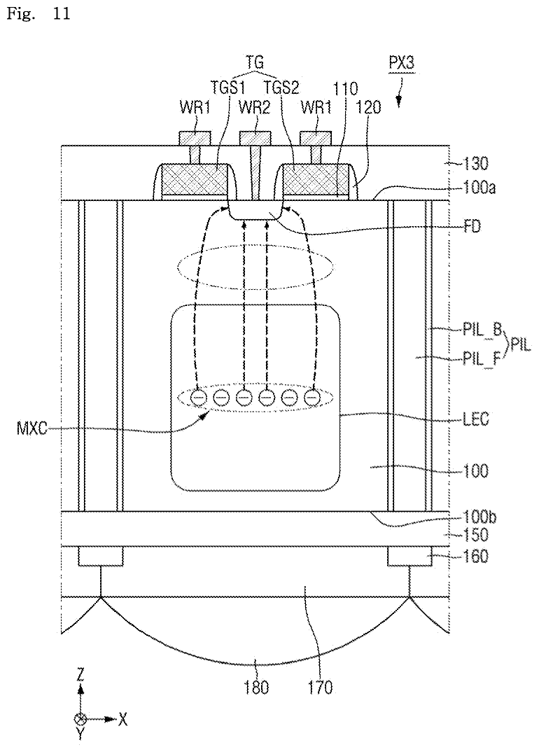

FIG. 10 is a schematic layout diagram of a pixel according to still another embodiment. FIG. 11 is a cross-sectional view taken along a line XI-XI′ of FIG. 10. A pixel PX3 illustrated in FIG. 10 and FIG. 11 may differ from the pixel PX1 in FIG. 6 and FIG. 7 including the horizontal single gate in that a transfer transistor TST of the pixel PX3 is of the third type including a horizontal double gate. A double gate may be a kind of a multi-gate and may include two sub-gates TGS1 and TGS2.

Referring to FIG. 10 and FIG. 11, the transfer gate TG may include the first sub-gate TGS1 and the second sub-gate TGS2. The first sub-gate TGS1 and the second sub-gate TGS2 may face each other in the first direction X. In an embodiment, a face of the first sub-gate TGS1 and a face of the second sub-gate TGS2 facing each other may be parallel to each other. However, embodiments are not limited thereto. The floating diffusion area FD may be disposed between the first sub-gate TGS1 and the second sub-gate TGS2. The floating diffusion area FD may further include a protrusion for contact which extends in the second direction Y as an extension direction of each of the first and second sub-gates TGS1 and TGS2.

When the transfer gate TG includes the first sub-gate TGS1 and the second sub-gate TGS2 facing each other in the first direction X, a stronger electric field may be applied to a space between the first sub-gate TGS1 and the second sub-gate TGS2. Therefore, the pixel PX3 in FIG. 11 may more efficiently transfer the charges generated/accumulated in the photoelectric conversion area LEC than the pixel PX in FIG. 7 employing a single gate.

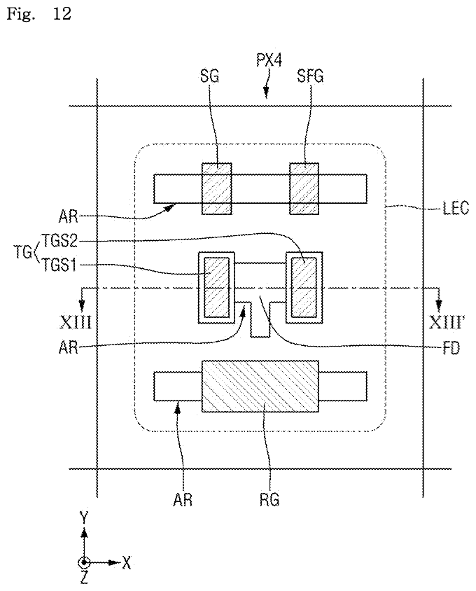

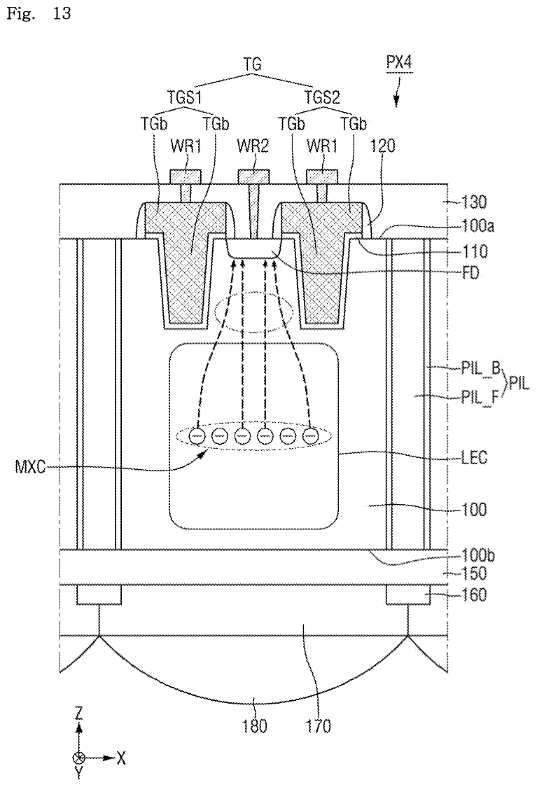

FIG. 12 is a schematic layout diagram of a pixel according to still yet another embodiment. FIG. 13 is a cross-sectional view taken along a line XIII-XIII′ of FIG. 12. A pixel PX4 illustrated in FIG. 12 and FIG. 13 may be of the fourth type in which the transfer transistor TST includes a vertical double gate. Referring to FIG. 12 and FIG. 13, the pixel PX4 according to this embodiment may be similar to the pixel PX2 of FIG. 10 and FIG. 11 in that the transfer gate TG is a double gate, but may differ from the pixel PX2 of FIG. 10 and FIG. 11 in that each of the first and second sub-gates TGS1 and TGS2 of the transfer gate TG of the pixel PX4 may be a vertical gate.

When each of the first sub-gate TGS1 and the second sub-gate TGS2 are implemented using the vertical gate, a spacing between the transfer gate TG and the maximum impurity concentration area MXC may be reduced, as described above with respect to FIG. 9, so that the pixel PX4 may transfer more efficiently the charges generated/accumulated in the photoelectric conversion area LEC. Furthermore, since the pixel PX4 illustrated in FIG. 12 employs the double gate structure including the first sub-gate TGS1 and the second sub-gate TGS2, a stronger electric field may be applied to a space between the first sub-gate TGS1 and the second sub-gate TGS2, thereby achieving more efficient charge transfer.

The same gate signal may be applied to the first sub-gate TGS1 and the second sub-gate TGS2 of the transfer gate TG as shown in FIGS. 10 to 13, or different gate signals may be applied thereto.

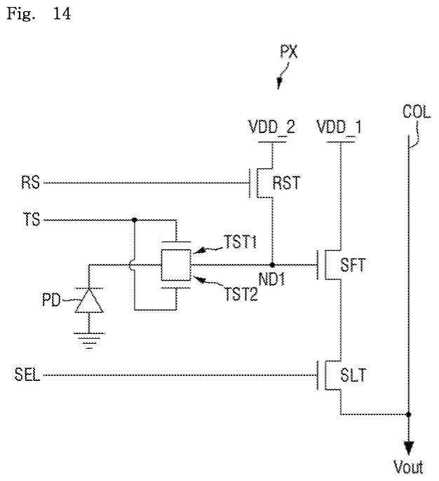

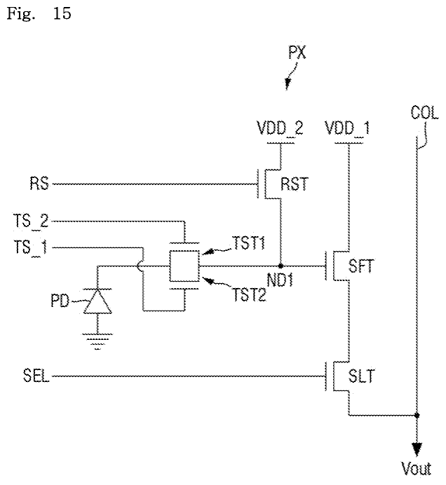

FIG. 14 and FIG. 15 illustrate related circuit diagrams.

FIG. 14 and FIG. 15 are respectively circuit diagrams of pixels of image sensors according to some embodiments.

As shown in FIG. 14, the first sub-gate TGS1 and the second sub-gate TGS2 may be connected to the same transfer line and may receive the same transfer signal TS. In embodiments, as shown in FIG. 15, the first sub-gate TGS1 and the second sub-gate TGS2 may be connected to different transfer lines and receive different transfer signals TS_1 and TS_2, respectively.

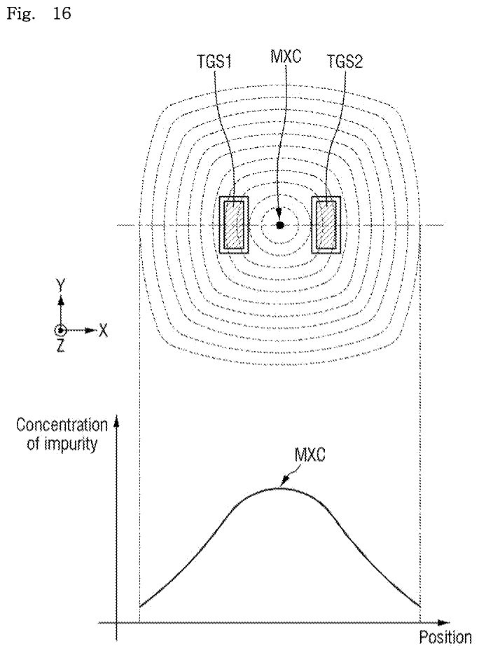

FIG. 16 is a schematic diagram of a layout of a pixel of a fourth type according to some embodiments, and a graph showing an impurity concentration based on a position thereof.

Referring to FIG. 16, the impurity ion concentration within the photoelectric conversion area LEC may vary depending on a position not only in the thickness direction (the third direction Z), but also in the horizontal direction (a direction along a plane defined by the first direction X and the second direction Y).

In an embodiment, in the ion implantation process, the impurity ions may not be implanted at the same concentration in an entirety of the photoelectric conversion area LEC in a plan view. For example, in the plan view, the impurity ions may be implanted such that a maximum concentration thereof is achieved at a center of the photoelectric conversion area LEC, while a lower concentration thereof is achieved in an outer area thereof, or direct implantation of the impurity ions to the outer area thereof is prevented. Even in this case, as described above, the implanted impurity ions may diffuse in all three-dimensional directions, so that the impurity ions may diffuse from an initial implanted position to positions around the initial implanted position.

A planar shape of an area MXC in which the impurity ions concentration is the highest may be an island shape such as at least one point, or a line shape. FIG. 16 illustrates an example in which the impurity ion maximum implantation area MXC is one point disposed at a center of the photoelectric conversion area LEC in a plan view. As shown in FIG. 16, the implanted impurity ions may diffuse in all directions in the plan view. Therefore, the highest impurity ion concentration may occur at the initially implanted position. The ion concentration at a specific position may decrease as a distance between the specific position and the initially implanted position increases. As shown in FIG. 16, points of the same impurity concentration are illustrated as connected to each other using a dotted line. Thus, concentric concentration distributions as shown in FIG. 16 may be achieved.

When the pixel PX4 includes the photoelectric conversion area LEC having the concentric impurity ion distributions as shown in FIG. 16, the first sub-gate TGS1 and the second sub-gate TGS2 of the pixel PX4 may face each other while the maximum impurity ion concentration point is disposed therebetween. As described above, a strong electric field is applied to a space between the first sub-gate TGS1 and the second sub-gate TGS2. Thus, when the maximum impurity concentration area MXC is disposed therebetween, the pixel PX4 may transmit more efficiently the charges generated/accumulated in the maximum impurity concentration area MXC.

From this point of view, in order to increase the transfer efficiency, the maximum impurity concentration area MXC may be disposed in the space positioned between the first sub-gate TGS1 and the second sub-gate TGS2, and not overlapping with the first sub-gate TGS1 and the second sub-gate TGS2. A spacing between the first sub-gate TGS1 and the maximum impurity concentration area MXC and a spacing between the second sub-gate TGS2 and the maximum impurity concentration area MXC may be equal to each other. However, embodiments are not limited thereto.

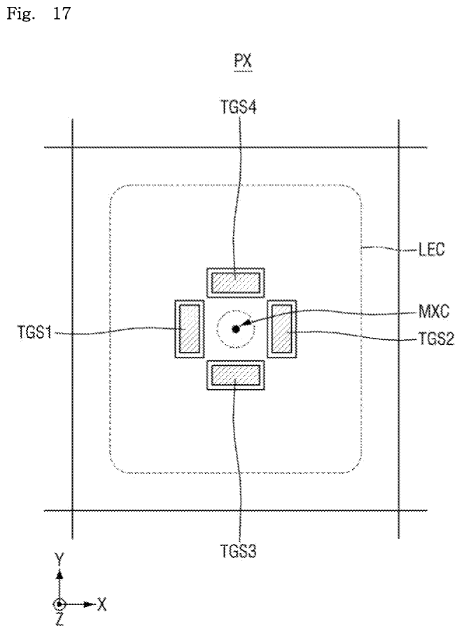

FIGS. 17 to 20 are layout diagrams of pixels according to various embodiments. FIG. 17 to FIG. 20 illustrate various planar shapes of multi/closed curved gates. Specifically, FIG. 17 to FIG. 20 illustrate a pixel of the fourth type in which the transfer gate TG of the pixel is a multi-gate including three or more sub-gates, or a closed-curved and vertical gate. However, embodiments do not only relate to the pixel of the fourth type, and may for example relate also to the pixel of the second type having substantially the same layout but having a horizontal gate.

FIG. 17 illustrates an example of a pixel PX in which the transfer gate TG may include the first sub-gate TGS1, the second sub-gate TGS2, a third sub-gate TES3 and a fourth sub-gate TES4 spaced from each other. The first sub-gate TGS1 and the second sub-gate TGS2 may have a shape extending along the second direction Y and face each other in the first direction X. The third sub-gate TES3 and the fourth sub-gate TES4 may have a shape extending in the first direction X and face each other in the second direction Y. The maximum impurity concentration area MXC in the photoelectric conversion area LEC may be an area surrounded with the four sub-gates TGS1, TGS2, TES3, and TES4. For example, the maximum impurity concentration area MXC may be positioned inside an inner area defined by a shortest closed curve connecting the sub-gates TGS1, TGS2, TES3, and TES4 to each other. The maximum impurity concentration area MXC may be non-overlapping with each of the sub-gates TGS1, TGS2, TES3, and TES4.

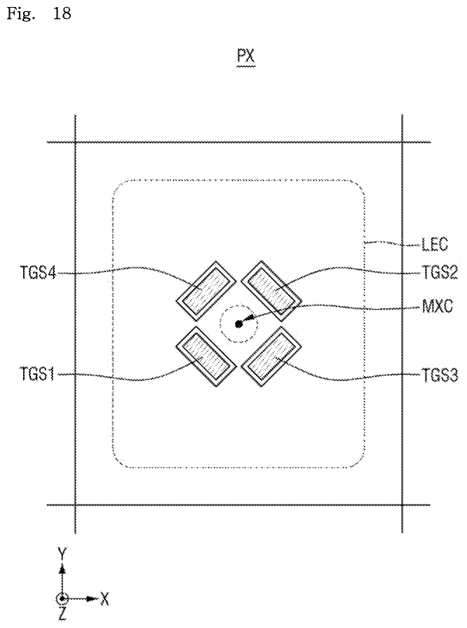

A pixel of FIG. 18 may be similar to the pixel PX of FIG. 17 in that the transfer gate TG includes the first sub-gate TGS1, the second sub-gate TGS2, the third sub-gate TES3 and the fourth sub-gate TES4 spaced from each other. However, the pixel PX of FIG. 18 differs from the pixel of FIG. 17 in that each of the first sub-gate TGS1, the second sub-gate TGS2, the third sub-gate TES3 and the fourth sub-gate TES4 extends in a diagonal direction different from the first direction X or the second direction Y. In an embodiment of FIG. 18, each of the first sub-gate TGS1 and the second sub-gate TGS2 extends in a first diagonal direction intersecting the first direction X and the second direction Y, while each of the third sub-gate TES3 and the fourth sub-gate TES4 extends in a second diagonal direction intersecting the first direction X and the second direction Y. In the embodiment of FIG. 18, the maximum impurity concentration area MXC in the photoelectric conversion area LEC is positioned inside an area surrounded with the four TGS1, TGS2, TES3, and TES4. The maximum impurity concentration area MXC may not overlap with each of the sub-gates TGS1, TGS2, TES3, and TES4.

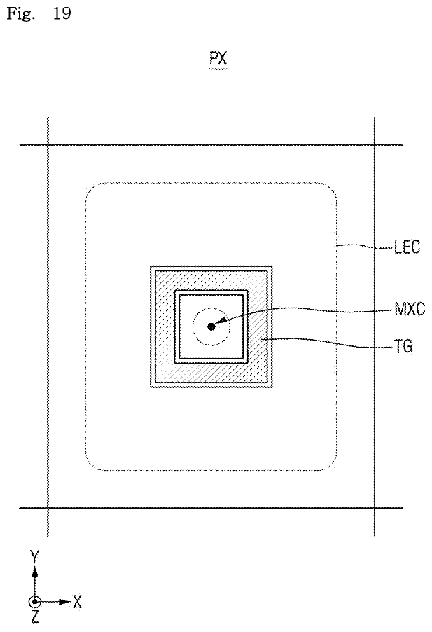

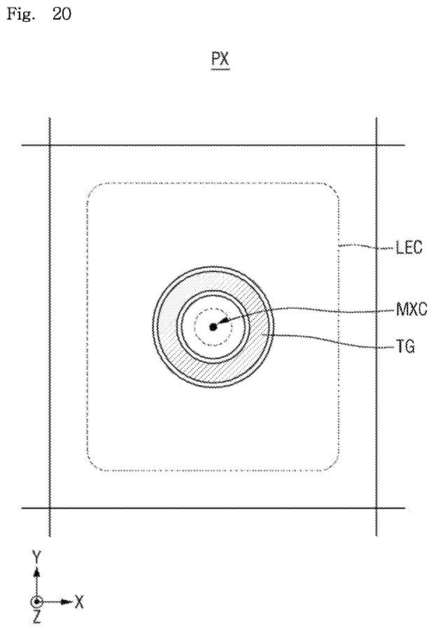

FIG. 19 illustrates an example of a pixel PX in which the transfer gate TG is formed in a rectangular closed curve in a plan view, and FIG. 20 illustrates an example of a pixel PX in which the transfer gate TG is formed in a circular closed curve in a plan view. In FIG. 19 and FIG. 20, the maximum impurity concentration area MXC in the photoelectric conversion area LEC is positioned inside an inner area defined by the closed curve of the transfer gate TG. The maximum impurity concentration area MXC may not overlap with the transfer gate TG.

In the embodiments of FIG. 17 to FIG. 20, the maximum impurity concentration area MXC may be positioned inside the inner area defined by the closed curve connecting the sub-gates to each other or by the closed curve of the transfer gate TG itself. The area MXC may face a larger amount of an inner side face of the gate in the plan view such that a stronger electric field may be applied to the area MXC and thus the generated/accumulated charges in the photoelectric conversion area LEC may be transferred more efficiently.

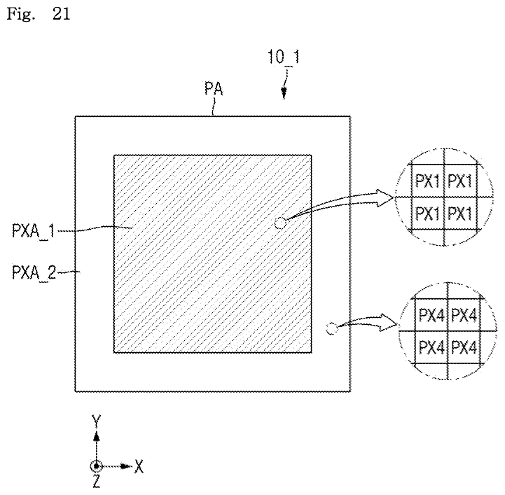

The image sensor may include at least two types of pixels PX among the various types of pixels PX as described above. Examples of some arrangements thereof are shown in FIGS. 21 to 23.

FIGS. 21 to 23 are respectively various views of pixel arrangements of an image sensor according to some embodiments.

Referring to FIG. 21, an image sensor 10_1 may include a first pixel area PXA_1 and a second pixel area PXA_2 in which pixels of different types are arranged, respectively. In FIG. 21, for example, the first pixel area PXA_1 includes an arrangement of the pixels PX1 of the first type, while the second pixel area PXA_2 includes an arrangement of the pixels PX4 of the fourth type. The pixel type applicable to each pixel area is not limited thereto. In FIG. 21, pixels of the same pixel type are arranged in one pixel area.

As shown in FIG. 21, the first pixel area PXA_1 may be disposed in an inner area of an entire active area of the image sensor. The first pixel area PXA_1 may have a rectangular shape. However, embodiments are not limited thereto. The second pixel area PXA_2 may be disposed in an outer area of the entire active area of the image sensor. The second pixel area PXA_2 may have a closed curve shape to surround the first pixel area PXA_1.

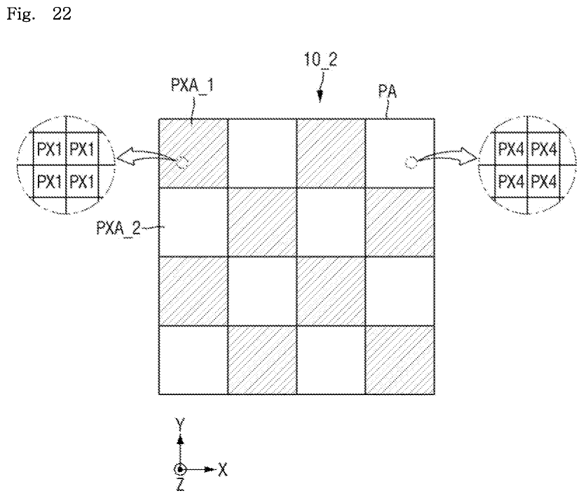

FIG. 22 illustrates that an image sensor 10_2 may include a plurality of first pixel areas PXA_1 and a plurality of second pixel areas PXA_2. Adjacent ones of the plurality of first pixel areas PXA_1 may be spaced from each other while another pixel area, that is, the second pixel area PXA_2 may be interposed therebetween. Similarly, adjacent ones of the plurality of second pixel areas PXA_2 may be spaced from each other while another pixel area, that is, the first pixel area PXA_1 may be interposed therebetween. In FIG. 22, a case where the plurality of first pixel areas PXA_1 and the plurality of second pixel areas PXA_2 are arranged in a checkered pattern is illustrated. However, embodiments are not limited thereto.

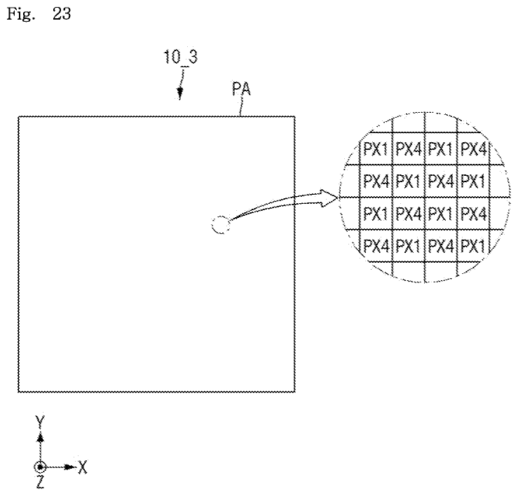

FIG. 23 illustrates that a pixel area of an image sensor 10_3 may include a plurality of pixel types alternatingly arranged with each other. As shown in FIG. 23, the pixels PX1 of the first type and the pixels PX4 of the fourth type may be alternatingly arranged with each other. Unlike the embodiments of FIG. 21 and FIG. 22 in which the pixels PX of the same type are adjacent to each other in the pixel area, pixels of different types may be adjacent to each other in the embodiment of FIG. 23.

The embodiment illustrated FIG. 23 may be combined with embodiments illustrated in FIG. 21 or FIG. 22. For example, one pixel area defined in FIG. 21 or FIG. 22 may include the plurality of pixel types alternatingly arranged with each other as shown in FIG. 23, and another pixel area defined in FIG. 21 or FIG. 22 may have an arrangement of pixel types different therefrom.

In the above description, an example in which one pixel PX includes one photoelectric conversion area LEC is illustrated. However, according to embodiments, one pixel PX may include a plurality of photoelectric conversion areas LEC. When one pixel PX includes a plurality of photoelectric conversion areas LEC, a plurality of transfer transistors TST may be provided in one pixel PX to transfer electric charges generated/accumulated in the photoelectric conversion areas LEC, respectively. In this case, the plurality of transfer transistors TST may be connected to one shared floating diffusion area FD. In embodiments, a plurality of floating diffusion areas FD may be respectively connected to the plurality of transfer transistors TST.

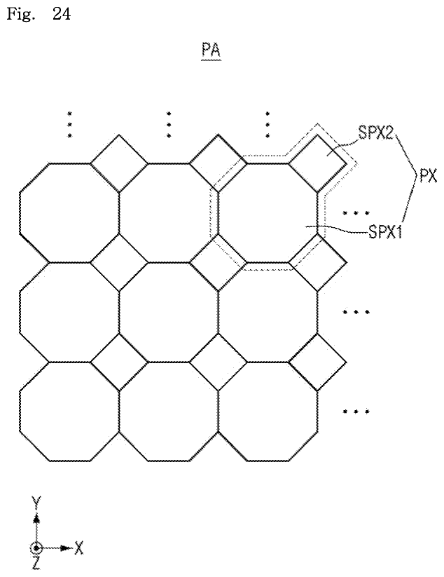

When the plurality of photoelectric conversion areas LEC and/or the plurality of floating diffusion areas FD are provided in one pixel PX and thus the plurality of transfer transistors TST corresponding thereto, respectively are provided therein, one pixel PX may include a plurality of sub-pixels, for example sub-pixel SPX1 and sub-pixel SPX2 discussed below with respect to FIG. 24. Each of the sub-pixels SPX1 and SPX2 may include each photoelectric conversion area LEC, and each transfer transistor TST and each floating diffusion area FD connected thereto. The reset transistor RST, the source follower transistor SFT, and the select transistor SLT may be shared by the plurality of sub-pixels SPX1 and SPX2. In embodiments, each reset transistor RST, each source follower transistor SFT, and each select transistor SLT may be provided individually in each of the sub-pixels SPX1 and SPX2.

When the pixel PX is divided into the plurality of sub-pixels SPX1 and SPX2, sensing precision at various illuminances may be increased, thereby increasing a dynamic range. For example, a pixel PX including a sub-pixel with high low-illuminance sensing precision and a sub-pixel with high high-illuminance sensing precision may have high sensing precision at an illuminance in a range from low-illuminance to high-illuminance.

When the roles of the sub-pixels SPX1 and SPX2 are different from each other, optimal conditions of the sub-pixels SPX1 and SPX2 may also be different from each other. Accordingly, the transfer efficiencies of the transfer transistors TST thereof may be different from each other. In this regard, even when the photoelectric conversion areas LEC of the sub-pixels SPX1 and SPX2 are designed to have different transfer efficiencies, different types of transfer transistors TST are applied to the sub-pixels SPX1 and SPX2, respectively, such that a difference between the transfer efficiencies thereof may be reduced, or a target transfer efficiency of each of the sub-pixels SPX1 and SPX2 may be achieved. More specific details thereof will become clearer based on illustrative embodiments as described below.

FIG. 24 is a partial layout diagram of a pixel of an image sensor according to some embodiments.

Referring to FIG. 24, a pixel PX includes a first sub-pixel SPX1 and a second sub-pixel SPX2. In a plan view, the first sub-pixel SPX1 has a larger area than that of the second sub-pixel SPX2. As described below, the first sub-pixel SPX1 may include a first photoelectric conversion area LEC1 and the second sub-pixel SPX2 may include a second photoelectric conversion area LEC2. In a plan view, the first photoelectric conversion area LEC1 may have a larger area size than that of the second photoelectric conversion area LEC2. Further, the first sub-pixel SPX1 may include a first floating diffusion area FD1, and the second sub-pixel SPX2 may include a second floating diffusion area FD2.

In an embodiment, the first sub-pixel SPX1 may have an octagonal shape, and the second sub-pixel SPX2 may have a quadrangular shape. The second sub-pixel SPX2 may be disposed adjacent to one of eight sides of the first sub-pixel SPX1. One side of the first sub-pixel SPX1 and one side of the second sub-pixel SPX2 may contact each other. However, embodiments are not limited thereto.

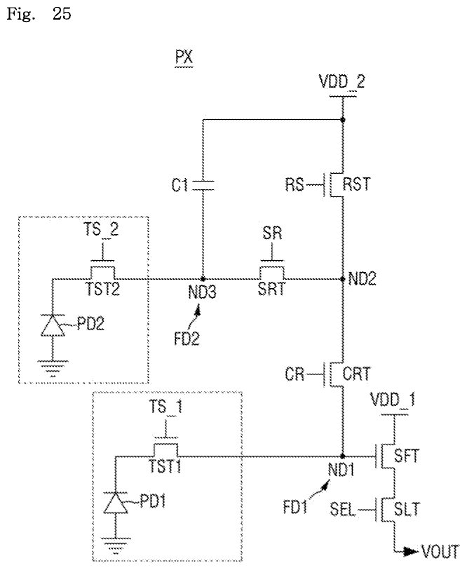

FIG. 25 is a circuit diagram of one pixel of FIG. 24.

Referring to FIG. 25, a pixel circuit includes a first photodiode PD1, a second photodiode PD2, a plurality of transistors and a capacitor C1. The plurality of transistors may include a transfer transistor TST, for example a first transfer transistor TST1 and a second transfer transistor TST2, a source follower transistor SFT, a select transistor SLT, a reset transistor RST, a connection transistor CRT, and a switching transistor SRT.

The first sub-pixel SPX1 may include the first photodiode PD1 and the first transfer transistor TST1, and the second sub-pixel SPX2 may include the second photodiode PD2 and the second transfer transistor TST2. The first photodiode PD1 may correspond to the first photoelectric conversion area LEC1, and the second photodiode PD2 may correspond to the second photoelectric conversion area LEC2. In a plan view, the first photodiode PD1 including the first photoelectric conversion area LEC1 having a relatively larger area may be referred to as a large photodiode, while the second photodiode PD2 including the second photoelectric conversion area LEC2 having a relatively smaller area may be referred to as a small photodiode.

The first sub-pixel SPX1 and the second sub-pixel SPX2 may share one source follower transistor SFT, one select transistor SLT and one reset transistor RST with each other.

More specifically, the first transfer transistor TST1 is disposed between the first photodiode PD1 and a first node ND1. The first node ND1 may be connected to the first floating diffusion area FD1. In embodiments, the first node ND1 itself may be the first floating diffusion area FD1. A gate of the first transfer transistor TST1 may be connected to a first transfer line and thus may receive a first transfer signal TS_1.

The source follower transistor SFT may be disposed between and connected to the first power voltage line providing the first power voltage VDD_1 and the output signal line COL. A gate of the source follower transistor SFT may be connected to the first node ND1 connected to the first floating diffusion area FD1.

The select transistor SLT may be disposed between the source follower transistor SFT and the output signal line COL. A gate of the select transistor SLT may be connected to a select line of a corresponding row and thus receive a select signal SEL.

The connection transistor CRT and the reset transistor RST may be disposed between the first node ND1 and the second power voltage line providing the second power voltage VDD_2. A second node ND2 may be defined between the connection transistor CRT and the reset transistor RST.

The connection transistor CRT may be disposed between the first node ND1 and the second node ND2. A gate of the connection transistor CRT is connected to a connection signal line. The connection transistor CRT may connect the first node ND1 and the second node ND2 to each other in response to a connection control signal CR provided from the connection signal line.

The reset transistor RST may be disposed between the second power voltage line and the second node ND2. A gate of the reset transistor RST may be connected to a reset line and thus receive a reset signal RS.

The second transfer transistor TST2 and the switching transistor SRT may be disposed between the second photodiode PD2 and the second node ND2. A third node ND3 may be defined between the second transfer transistor TST2 and the switching transistor SRT.

The second transfer transistor TST2 may be disposed between and connected to the second photodiode PD2 and the third node ND3. The third node ND3 may be connected to the second floating diffusion area FD2. In embodiments, the third node ND3 itself may be the second floating diffusion area FD2. A gate of the second transfer transistor TST2 may be connected to a second transfer line. A second transfer signal TS_2 as a scan signal different from the first transfer line may be applied to the second transfer line. Accordingly, the first transfer transistor TST1 and the second transfer transistor TST2 may be turned on and off at different times.

The switching transistor SRT may be disposed between the third node ND3 and the second node ND2. A gate of the switching transistor SRT may be connected to a switch control line. The switching transistor SRT may connect the third node ND3 and the second node ND2 to each other in response to a switch control signal SR applied through the switch control line.

The capacitor C1 may be disposed between the third node ND3 and the second power voltage line. The capacitor C1 may store therein charges overflowing from the second photodiode PD2.

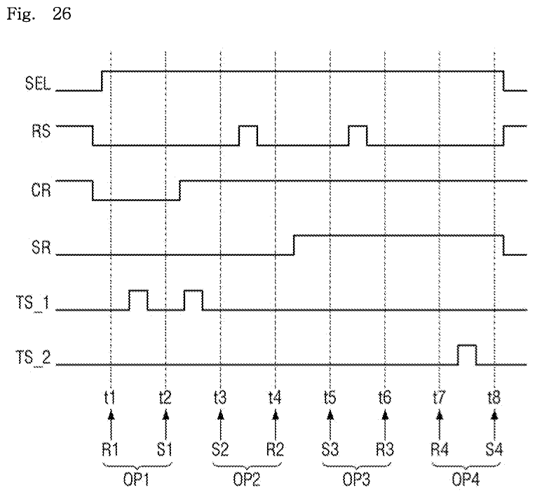

FIG. 26 is an illustrative timing diagram for illustrating an operation of one pixel with a circuit structure of FIG. 25. FIG. 26 shows a timing of a signal applied to one pixel PX disposed in a row to be readout at a corresponding time. At the same time, signals different from those of the illustrated example may be applied to pixels PX corresponding to another row that is not selected as a readout target. For example, signal waveforms that appear before or after four operations OP1, OP2, OP3, and OP4 in FIG. 26 may be applied to the pixels PX corresponding to another row that is not selected as a readout target.

In the timing diagram of FIG. 26, waveforms of the select signal SEL, the reset signal RS, the connection control signal CR, the switch control signal SR, the first transfer signal TS_1, and the second transfer signal TS_2 are sequentially shown. Each of the signal waveforms swings between a high-level voltage and a low-level voltage. The high-level voltage may be a turn-on signal for turning on a transistor to which the signal is applied. The low-level voltage may be a turn-off signal for turning off a transistor to which the signal is applied.

Referring to FIG. 25 and FIG. 26, a readout operation of the pixel PX may include four operations. Specifically, the readout operation of the pixel PX may include a first operation OP1, a second operation OP2, a third operation OP3, and a fourth operation OP4 sequentially performed in the illustrated order. The four operations may respectively include signal operations S1, S2, S3, and S4, and may respectively further include reset operations R1, R2, R3, and R4. In one operation, the reset operation may be performed before the signal operation, or may be performed after the signal operation. In each of some operations, the reset operation may be omitted. During each of the four operations, the select signal SEL is maintained at a high-level.

During a time before the readout, that is, during a time before the first operation OP1, each of the select signal SEL, the switch control signal SR, the first transfer signal TS_1 and the second transfer signal TS_2 may be maintained at a low-level, while each of the reset signal RS and the connection control signal CR may be maintained at a high-level.

In the first operation OP1, a first reset operation R1 may be first performed at a first time t1, and then a first signal operation S1 may be performed at a second time t2.

Specifically, the select signal SEL may be switched from a low-level to a high-level by the first time t1 at which the first reset operation R1 is performed. Each of the reset signal RS and the connection control signal CR may be switched from a high-level to a low-level by the first time t1. During the first reset operation R1, the charge accumulated in the first node ND1 may be converted to a first reset voltage VR1 via the source follower transistor SFT and then may be output.

Subsequently, the first signal operation S1 may be performed at the second time t2. During a time period between the first time t1 and the second time t2, the first transfer signal TS_1 may be switched from a low-level to a high-level and then switched back to a low-level. While the first transfer signal TS_1 is maintained at a high-level, the first transfer transistor TST1 may be turned on for a predetermined time duration and then turned off. While the first transfer transistor TST1 is turned on, the first node ND1 may be connected to the first photodiode PD1. Thus, the charge stored in the first photodiode PD1 may be transferred to the first node ND1, that is, the first floating diffusion area FD1. The charge transferred to the first node ND1 may be converted into the first signal voltage VS1 via the source follower transistor SFT and then may be output.

After the first operation OP1, the second operation OP2 may be performed. In the second operation OP2, a second signal operation S2 may be first performed at a third time t3, and then a second reset operation R2 may be performed at a fourth time t4.

Specifically, during a time period between the second time t2 and the third time t3, the connection control signal CR may be switched from a low-level to a high-level to turn on the connection transistor CRT. As a result, the first node ND1 and the second node ND2 may be connected to each other.

Further, during a time period between the second time t2 and the third time t3, the first transfer signal TS_1 may be switched from a low-level to a high-level and then switched back to a low-level while the connection transistor CRT is turned on. While the connection transistor CRT and the first transfer transistor TST1 are simultaneously turned on, the first node ND1 may be connected to the first photodiode PD1 and the second node ND2. Accordingly, during this time duration, charges of the first photodiode PD1 and the second node ND2 may be transferred to the first node ND1. The charge transferred to the first node ND1 may be converted into a second signal voltage VS2 via the source follower transistor SFT and then may be output.

Subsequently, the second reset operation R2 may be performed at the fourth time t4. During a time period between the third time t3 and the fourth time t4, the reset signal RS may be switched from a low-level to a high-level and then switched back to a low-level. While the reset signal RS is maintained at a high-level, the reset transistor RST may be turned on, and the charges of the first node ND1 and the second node ND2 may be reset. The reset charges of the first node ND1 and the second node ND2 may be converted into a second reset voltage VR2 via the source follower transistor SFT and then may be output.

After the second operation OP2, the third operation OP3 may be performed. In the third operation OP3, a third signal operation S3 may be first performed at a fifth time t5, and then a third reset operation R3 may be performed at a sixth time t6.

Specifically, during a time period between the fourth time t4 and the fifth time t5, the switch control signal SR may be switched from a low-level to a high-level to turn on the switching transistor SRT. As a result, and the second node ND2 and the third node ND3 connected to capacitor C1 may be connected to each other. That is, during this time duration, all of the first node ND1, the second node ND2, and the third node ND3 may be connected to each other, and the charges accumulated therein may be converted into a third signal voltage VS3 via the source follower transistor SFT and then may be output. The third signal voltage VS3 may include an output corresponding to the charges accumulated in the capacitor C1.

Subsequently, the third reset operation R3 may be performed at the sixth time t6. During a time duration between the fifth time t5 and the sixth time t6, the reset signal RS may be switched from a low-level to a high-level and then switched back to a low-level. While the reset signal RS is maintained at a high-level, the reset transistor RST may be turned on, and charges of the first node ND1, the second node ND2, and the third node ND3 may be reset. The reset charges of the first node ND1, the second node ND2, and the third node ND3 may be converted to a third reset voltage VR3 via the source follower transistor SFT and then may be output.

After the third operation OP3, the fourth operation OP4 may be performed. In the fourth operation OP4, a fourth reset operation R4 may be first performed at a seventh time t7, and then a fourth signal operation S4 may be performed at an eighth time t8.

The fourth reset operation R4 may be performed without changing an applied signal. That is, during a time period between the sixth time t6 and the seventh time t7, the signal may not be changed. Charges accumulated in the first node ND1, the second node ND2, and the third node ND3 may be converted to a fourth reset voltage VR4 via the source follower transistor SFT and then may be output.

In some embodiments, the fourth reset operation R4 may be omitted. When the fourth reset operation R4 is omitted, the third reset voltage VR3 generated in the third reset operation R3 may be used as a reference voltage.

Subsequently, the fourth signal operation S4 may be performed at the eighth time t8. During a time period between the seventh time t7 and the eighth time t8, the second transfer signal TS_2 may be switched from a low-level to a high-level and then switched back to a low-level. While the second transfer signal TS_2 is maintained at a high-level, the second transfer transistor TST2 may be turned on so that the third node ND3 may be connected to the second photodiode PD2. Thus, the charge stored in the second photodiode PD2 may be transferred to the third node ND3, that is, the second floating diffusion area FD2. At this point, the third node ND3 may be connected to the second node ND2 and the first node ND1, so that the charges transferred to the third node from the second photodiode PD2 together with the charges previously accumulated in the third node ND3 and the second node ND2 are transferred to the first node ND1. Then, the charges transferred to the first node ND1 may be converted to a fourth signal voltage VS1 via the source follower transistor SFT and then may be output.

After the fourth operation OP4, each of the select signal SEL and the switch control signal SR may be switched from a high-level to a low-level, and the reset signal RS may be switched from a low-level to a high-level.

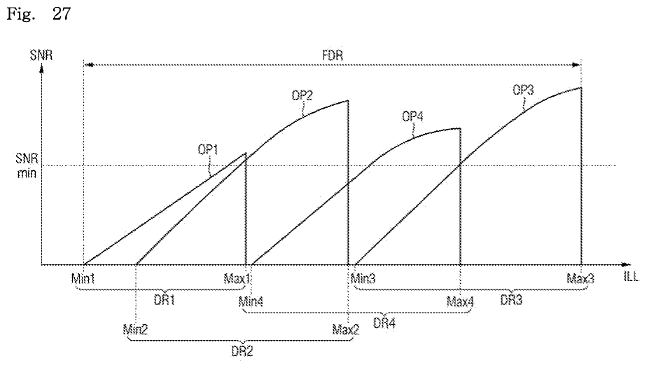

FIG. 27 is a graph showing a signal-to-noise ratio based on illuminance of a pixel under the pixel operation of FIG. 26.

As shown in FIG. 27, the image sensor detects minimum illuminances Min1, Min2, Min3, and Min4 and maximum illuminances Max1, Max2, Max3, and Max4 during the pixel PX operation. The minimum illuminances Min1, Min2, Min3, and Min4 and the maximum illuminances Max1, Max2, Max3, and Max4 may be related to a dynamic range. As described above, the first to fourth operations OP1 to OP4 may have different connected nodes. Therefore, the first to fourth operations OP1 to OP4 may have different minimum illuminances and maximum illuminances. That is, the first to fourth operations OP1 to OP4 may have different dynamic ranges.

For example, in the first operation OP1 in which the charge generated from the first photodiode PD1 is transferred to the first node ND1 and then is converted to the signal voltage which in turn is output, the pixel PX has a relatively small capacitance, such that a first dynamic range DR1 of the first operation OP1 has a dynamic range of low-illuminance. Therefore, the first operation OP1 may be usefully used for image sensing in a low-illuminance environment.

In the second operation OP2, the first node ND1 and the second node ND2 may be connected to each other, such that the pixel PX may have a larger capacitance than that in the first operation OP1. Therefore, a second dynamic range DR2 of the second operation OP2 has a larger value than that of the first dynamic range DR1. The second dynamic range DR2 may partially overlap with the first dynamic range DR1, and may have a larger maximum signal-to-noise value SNR than that of the first dynamic range DR1.

In the third operation OP3, not only the first node ND1 and the second node ND2 but also the third node ND3 to which the capacitor C1 with large capacitance is connected may be connected to each other, so that the pixel PX may have a larger full well capacity. Accordingly, the third operation OP3 may have a third dynamic range DR3 larger than the second dynamic range DR2. The third dynamic range DR3 may not overlap with the second dynamic range DR2. That is, the minimum illuminance Min3 of the third dynamic range DR3 may be greater than the maximum illuminance Max2 of the second dynamic range DR2.

The third dynamic range DR3 implemented in the third operation OP3 may be usefully used for image sensing in a high-illuminance environment. The third dynamic range DR3 may have a larger maximum signal-to-noise value SNR than that of the second dynamic range DR2.

In the fourth operation OP4, the charges generated from the second photodiode PD2 may be transferred to the third node ND3 and then may be converted to the signal voltage which in turn may be output. In the fourth operation OP4, all of the first node ND1, the second node ND2 and the third node ND3 are connected to each other as in the third operation OP3. However, the fourth operation OP4 may be performed after the readout from the capacitor C1 connected to the third node ND3 is completed and then is reset. Therefore, the fourth operation OP4 may have a fourth dynamic range DR4 smaller than the third dynamic range DR3. The fourth dynamic range DR4 may be positioned between the second dynamic range DR2 and the third dynamic range DR3. The minimum illuminance Min4 of the fourth dynamic range DR4 may be smaller than the maximum illuminance Max2 of the second dynamic range DR2, but may be greater than the maximum illuminance Min1 of the first dynamic range DR1. The maximum illuminance Max4 of the fourth dynamic range DR4 may be greater than the minimum illuminance Min3 of the third dynamic range DR3 and may be smaller than the maximum illuminance Max3. The maximum signal-to-noise value SNR of the fourth dynamic range DR4 may be greater than the maximum signal-to-noise value SNR of the first dynamic range DR1 and may be smaller than the maximum signal-to-noise value SNR of the second dynamic range DR2. However, embodiments are not limited thereto.

In this manner, when the pixel PX has the first photodiode PD1 and the second photodiode PD2 having different sizes, the dynamic ranges DR having various ranges may be set by diversifying the connection relationship between the nodes. Accordingly, the pixel PX may output a signal having a full dynamic range including the first to fourth dynamic ranges DR1, DR2, DR3, and DR4, such that a full well capacity FDR of the image sensor may increase. Further, because a plurality of dynamic ranges partially overlap each other, an output equal to or greater than a reference signal-to-noise ratio (SNRmin) as a minimum reference required in a broad illuminance range may be obtained, so that image sensing quality may be improved.

The above-described dynamic ranges may be precisely controlled by adjusting capacitances of the capacitor C1 and the photoelectric conversion element. As described above, in the plan view, a size of the first photoelectric conversion area LEC1 may be set to be larger than that of the second photoelectric conversion area LEC2. The photoelectric conversion areas LEC with different area sizes may achieve different capacitances. When the capacitances of the photoelectric conversion areas LEC are different from each other, the transfer efficiencies thereof may be different from each other. Further, the different photoelectric conversion areas LEC1 and LEC2 may have different maximum impurity concentration areas, that is, different maximum charge generation/accumulation areas. Thus, the transfer efficiencies thereof may be different from each other. When one of the first photoelectric conversion area LEC1 and the second photoelectric conversion area LEC2 has a lower transfer efficiency than that of the other thereof, it may be difficult to increase the full well capacity.

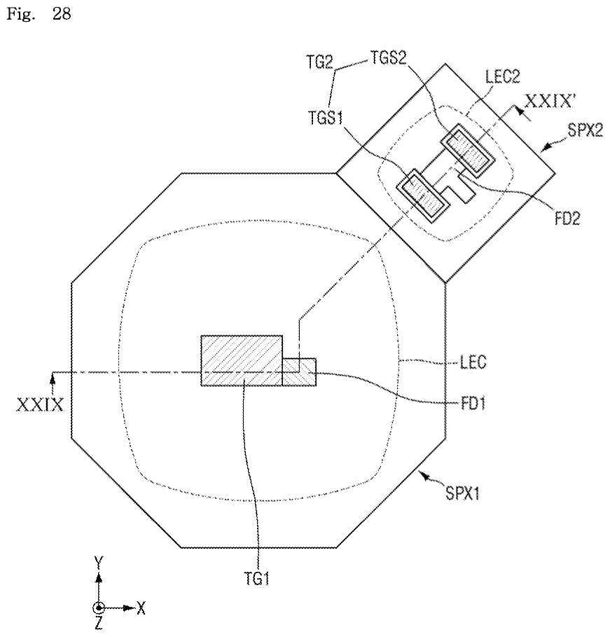

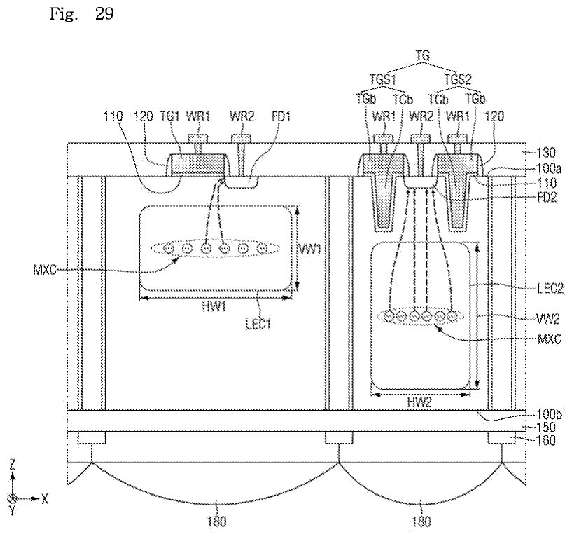

In this regard, different pixel types as described above with reference to FIGS. 6 to 20 may be respectively applied to the first photodiode PD1 of the first sub-pixel SPX1 and the second photodiode PD2 of the second sub-pixel SPX2 having the above-mentioned different characteristics. An example of this is described in more detail below with reference to FIG. 28 and FIG. 29.

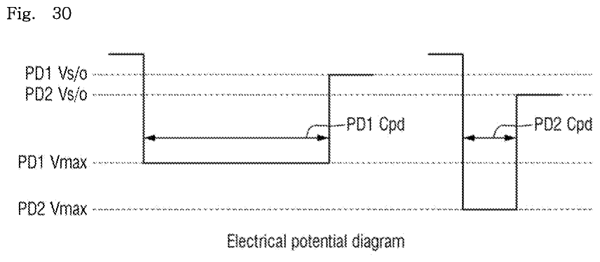

FIG. 28 is a schematic layout diagram of a pixel PX according to some embodiments. FIG. 28 shows only the photoelectric conversion areas LEC1 and LEC2, the transfer gates TG1 and TG2 and the floating diffusion areas FD1 and FD2 of the sub-pixels SPX1 and SPX2, respectively, for convenience of illustration. FIG. 29 is a cross-sectional view of a combination of the first sub-pixel and the second sub-pixel of FIG. 28. FIG. 30 is a schematic diagram showing a relationship between capacitance and electric potential of each of a first photodiode of a first sub-pixel and a second photodiode of a second sub-pixel.

Referring to FIG. 28, the first transfer gate TG1 of the first sub-pixel SPX1 may be disposed in a center of the first photoelectric conversion area LEC1. The first transfer gate TG1 may have a shape extending in the first direction X, and the first floating diffusion area FD1 may be disposed on one side thereof.

The second transfer gate TG2 of the second sub-pixel SPX2 may include the first sub-gate TGS1 and the second sub-gate TGS2 facing each other and spaced from each other. A direction in which each of the first sub-gate TGS1 and the second sub-gate TGS2 extend may be a diagonal direction. The second floating diffusion area FD2 may be disposed between the first sub-gate TGS1 and the second sub-gate TGS2. The second floating diffusion area FD2 may further include a protrusion for contact extending in the diagonal direction.

In a plan view, the first photoelectric conversion area LEC1 of the first sub-pixel SPX1 may have a larger area than that of the second photoelectric conversion area LEC2 of the second sub-pixel SPX2, as shown in FIG. 28. Accordingly, the first photodiode PD1 of the first sub-pixel SPX1 may have a larger capacitance than that of the second photodiode PD2 of the second sub-pixel SPX2.

Because the first sub-pixel SPX1 and the second sub-pixel SPX2 may have different capacitances, maximum electric potentials of the photodiodes PD1 and PD2 of the sub-pixels SPX1 and SPX2 may be different from each other as shown in FIG. 30. A difference between shut-off electric potential Vs/o and the maximum electric potentials Vmax of each of the photodiodes PD1 and PD2 and capacitance Cpd of each of the photodiodes PD1 and PD2 may be related to maximum charge storage capacity of each of the photodiodes PD1 and PD2. For example, the maximum charge storage capacity of each of the photodiodes PD1 and PD2 may be proportional to the difference between the shut-off electric potential Vs/o and the maximum electric potentials Vmax of each of the photodiodes PD1 and PD2 and the capacitance Cpd thereof.

Because the second photoelectric conversion area LEC2 may have a smaller width in the horizontal direction than that of the first photoelectric conversion area LEC1 (HW2<HW1), the second photoelectric conversion area LEC2 may have smaller capacitance Cpd corresponding to the smaller width. This may be more disadvantageous in terms of charge storage capacity. To compensate for this disadvantage, the second photodiode PD2 may be designed to have a larger electric potential difference, that is, the difference between the shut-off electric potential Vs/o and the maximum electric potentials Vmax than that of the first photodiode PD1. The electric potential difference may be based on the maximum electric potential Vmax and the shut-off electric potential Vs/o. Thus, the maximum electric potential Vmax of the second photodiode PD2 may be designed to be further raised to compensate for the charge storage capacity thereof. FIG. 30 illustrates a case in which the shut-off electric potential PD2 Vs/o of the second photodiode PD2 is lower than the shut-off electric potential PD1 Vs/o of the first photodiode PD1. However, embodiments are not limited thereto. The shut-off electric potential PD2 Vs/o of the second photodiode PD2 may be higher than or equal to the shut-off electric potential PD1 Vs/o of the first photodiode PD1.

In this regard, the maximum electric potential Vmax pf the second photodiode PD2 may be adjusted in the above manner such that the difference between the charge storage capacities of the first photodiode PD1 and the second photodiode PD2 may be reduced compared to that when the maximum electric potentials of the first photodiode PD1 and the second photodiode PD2 are equal to each other. In an embodiment, the maximum electric potential Vmax second photodiode PD2 may be adjusted such that the difference between the charge storage capacities of the first photodiode PD1 and the second photodiode PD2 is zero or is within 30% or within 10%. However, embodiments are not limited thereto. In embodiments, the maximum electric potential PD1 Vmx of the first photodiode PD1 instead of the second photodiode PD2 may be adjusted to be further lowered. In embodiments, both the maximum electric potentials PD2 Vmax and PD1 Vmax of the second photodiode PD2 and the first photodiode PD1 may be adjusted from default settings.

Referring to FIG. 29, when the second photoelectric conversion area LEC2 of the second photodiode PD2 has a greater maximum electric potential than that of the first photoelectric conversion area LEC1 of the first photodiode PD1, the second photoelectric conversion area LEC2 may have a greater maximum concentration in the maximum impurity concentration area MXC than that in the maximum impurity concentration area MXC of the first photoelectric conversion area LEC1. When the maximum impurity concentration areas MXC thereof are different from each other, an amount by which the impurities diffuse in the third direction Z in the first photodiode PD1 may be different from that in the second photodiode PD2. Thus, dimensions VW1 and VW2 in the third direction Z of the photoelectric conversion areas LEC1 and LEC2 may be different from each other. For example, as shown in FIG. 29, the second photoelectric conversion area LEC2 having a smaller area in a plan view may have a larger dimension in the third direction Z than that of the first photoelectric conversion area LEC1, such that for example VW2>VW1.

Further, a depth of the maximum impurity concentration area MXC in the first photoelectric conversion area LEC1 and a depth of the maximum impurity concentration area MXC in the second photoelectric conversion area LEC2 may be different from each other. For example, as shown in FIG. 29, the depth of the maximum impurity concentration area MXC in the second photoelectric conversion area LEC2 may be greater than the depth of the maximum impurity concentration area MXC in the first photoelectric conversion area LEC1.

When the depths of the maximum impurity concentration areas MXC of the sub-pixels SPX1 and SPX2 are different from each other, and the maximum electric potentials thereof are different from each other, the sub-pixels SPX1 and SPX2 respectively having the transfer transistors having the same structure may be highly likely to exhibit different transfer efficiencies. For example, when the first sub-pixel SPX1 and the second sub-pixel SPX2 respectively have the transfer transistors having the same structure, the transfer efficiency of the second sub-pixel SPX2 having the deeper MXC and having a higher electric potential may be relatively low. When the transfer efficiency of the second sub-pixel SPX2 is lowered, it may be difficult to realize the full well capacity.

In embodiments the different types of pixel PX structures as discussed above may be respectively applied to the first sub-pixel SPX1 and the second sub-pixel SPX2 shown in FIGS. 28 and 29, thereby reducing the difference between the transfer efficiencies of the first sub-pixel SPX1 and the second sub-pixel SPX2. Specifically, the first transfer gate TG1 of the first sub-pixel SPX1 may be implemented using a horizontal single gate which may be employed in the pixel of the first type, while the second transfer gate TG2 of the second sub-pixel SPX2 may be implemented using a vertical double gate which may be employed in the pixel of the fourth type. As described above, the vertical double gate may have higher transfer efficiency than that of the horizontal single gate, thereby reducing the difference between the transfer efficiencies of the first sub-pixel SPX1 and the second sub-pixel SPX2. Unlike the illustrated example, the second sub-pixel SPX2 may be implemented using the pixel of the second type or the pixel of the third type.

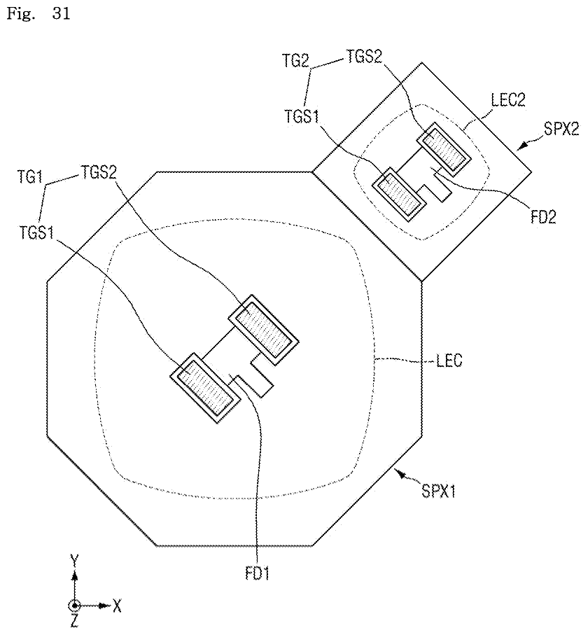

FIG. 31 is a schematic layout diagram of one pixel according to still another embodiment.

The pixel illustrated in FIG. 31 may differ from the embodiment of FIG. 28 in that each of the transfer transistors TST1 and TST2 of the first sub-pixel SPX1 and the second sub-pixel SPX2 may have a vertical double gate with relatively high transfer efficiency.

When the first transfer gate TG1 of the first sub-pixel SPX1 includes a vertical double gate, the first sub-pixel SPX1 may exhibit improved transfer efficiency.

Even when the transfer gates TG1 and TG2 of the first sub-pixel SPX1 and the second sub-pixel SPX2 respectively have the vertical double gates, the transfer efficiencies thereof may be controlled to be different from each other via adjustment of various variables.

For example, a spacing between the first sub-gate TGS1 and the second sub-gate TGS2 included in the transfer gate TG may act as a factor determining the transfer efficiency. In one example, the smaller the spacing between the first sub-gate TGS1 and the second sub-gate TGS2, the greater the transfer efficiency may be. In embodiments, the opposite result thereto may be obtained depending on an area size of the photoelectric conversion area LEC or an amount of charges accumulated therein.

A size of each of the first sub-gate TGS1 and the second sub-gate TGS2 may also influence the transfer efficiency. In general, as widths of the first sub-gate TGS1 and the second sub-gate TGS2 facing each other increase, the transfer efficiency increases.

Further, the transfer efficiency may vary depending on a depth by which each of the first sub-gate TGS1 and the second sub-gate TGS2 is vertically buried. In one example, as the depth by which each of the first sub-gate TGS1 and the second sub-gate TGS2 is vertically buried increases, the transfer efficiency may increase.

In order for the second photoelectric conversion area LEC2 of the second sub-pixel SPX2 to have further higher maximum electric potential to further increase the transfer efficiency of the second sub-pixel SPX2, the above-mentioned parameters may be adjusted.

For example, the spacing between the first sub-gate TGS1 and the second sub-gate TGS2 of the second sub-pixel SPX2 may be set to be smaller than the spacing between the first sub-gate TGS1 and the second sub-gate TGS2 of the first sub-pixel SPX1. Further, the depth by which each of the first sub-gate TGS1 and the second sub-gate TGS2 of the second sub-pixel SPX2 is buried may be set to be larger than the depth by which each of the first sub-gate TGS1 and the second sub-gate TGS2 of the second sub-pixel SPX2 is buried. The relations about the variables as defined above may be satisfied simultaneously.

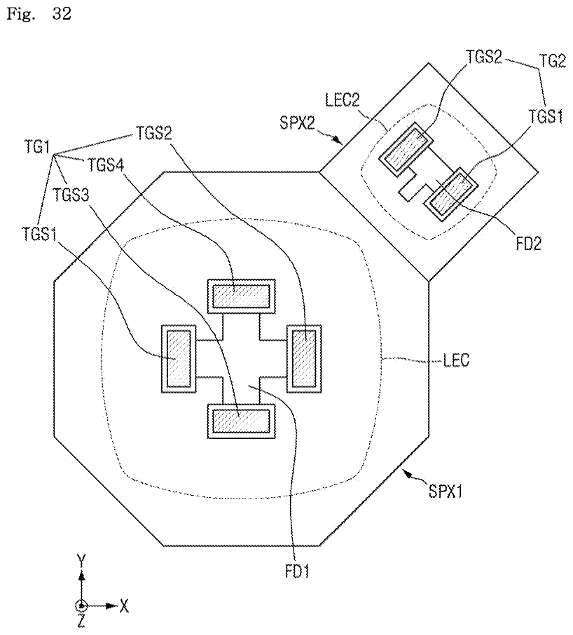

FIG. 32 is a schematic layout diagram of one pixel according to still yet another embodiment.

As shown in FIG. 32, each of the sub-pixels SPX1 and SPX2 of the pixel PX may have a vertical multi-gate. In FIG. 32, the first transfer transistor TST1 of the first sub-pixel SPX1 may have a vertical multi-gate structure including four sub-gates TGS1, TGS2, TES3, and TES4. The first floating diffusion area FD1 may be disposed between the four sub-gates TGS1, TGS2, TES3, and TES4. As shown in FIG. 32, an extension direction of each of the first sub-gate TGS1 and the second sub-gate TGS2 of the second sub-pixel SPX2 may be a diagonal direction different from that illustrated in FIG. 31.

In embodiments, the first transfer transistor TST1 may include a vertical double gate, and the second transfer transistor TST2 may include a vertical multi-gate. In embodiments, each of the first transfer transistor TST1 and the second transfer transistor TST2 may include a vertical multi-gate.

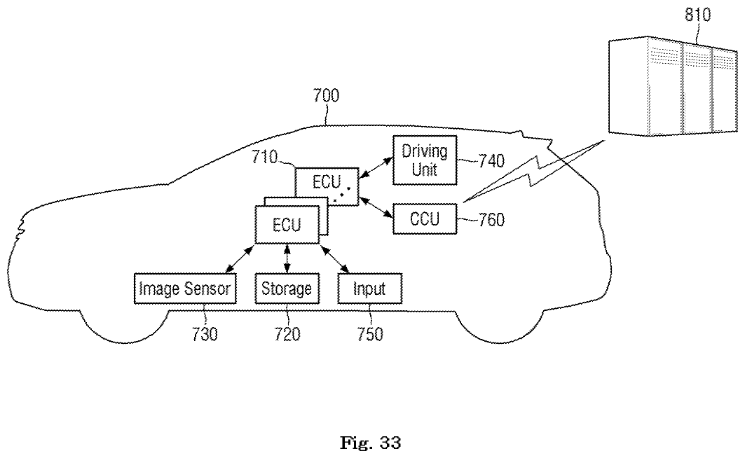

Hereinafter, a vehicle including an image sensor according to some embodiments will be described with reference to FIG. 33.

FIG. 33 is a diagram of a vehicle including an image sensor according to some embodiments.

Referring to FIG. 33, a vehicle 700 may include a plurality of electronic control units (ECU) 710, and a storage device 720.

Each electronic control unit of the plurality of electronic control units 710 may be electrically, mechanically, and communicatively connected to at least one device among a plurality of devices provided in the vehicle 700, and may control an operation of the at least one device based on one function execution command.

In this regard, the plurality of devices in the vehicle 700 may include an image sensor 730 that acquires an image required to perform at least one function, and a driving unit 740 that performs the at least one function.

The image sensor 730 may include each of the image sensors according to the various embodiments as described above. The image sensor 730 may act as an automotive image sensor.

The driving unit 740 may include a fan and a compressor of an air conditioning device, a fan of a ventilation device, an engine and a motor of a powering device, a motor of a steering device, a motor and a valve of a braking device, and an opening/closing device of a door or a tail gate, etc.

The plurality of electronic control units 710 may communicate with the image sensor 730 and the driving unit 740 using, for example, at least one of Ethernet, low-voltage differential signal (LVDS) communication, and LIN (Local Interconnect Network) communication.

The plurality of electronic control units 710 may determine whether execution of a function is necessary based on information obtained through the image sensor 730, and may control an operation of the driving unit 740 that performs the corresponding function when it is determined that the function needs to be performed. The plurality of electronic control units 710 may control an amount of the operation based on the obtained information. In this regard, the plurality of electronic control units 710 may store the acquired image in the storage device 720 or read and use information stored in the storage device 720.

The plurality of electronic control units 710 may control an operation of the driving unit 740 that performs the corresponding function based on the function execution command input through the input unit 750. In embodiments, the plurality of electronic control units 710 may identify a setting amount corresponding to the information input through the input unit 750 and may control an operation of the driving unit 740 that performs the corresponding function based on the identified setting amount.

Each of the electronic control units 710 may independently control one function or may control one function in association with another electronic control unit.

For example, when a distance to an obstacle as detected using a distance detector is within a reference distance, an electronic control unit of a collision avoidance device may output a warning sound against collision with the obstacle through a speaker.

An electronic control unit of an autonomous driving control device may receive navigation information, road image information, and information on a distance to an obstacle in association with an electronic control unit of a vehicle terminal, an electronic control unit of an image acquisition unit, and the electronic control unit of the collision avoidance device. Then, the electronic control unit of an autonomous driving control device may control the powering device, the braking device, and the steering device using the received information to perform autonomous driving.

A CCU (Connectivity Control Unit) 760 may be electrically, mechanically and communicatively connected to each of the plurality of electronic control units 710, and may perform communication with each of the plurality of electronic control units 710.

In other words, the CCU 760 may communicate directly with the plurality of electronic control units 710 disposed inside the vehicle, or may communicate with an external server or may communicate with an external terminal via an interface.

In this regard, the CCU 760 may communicate with the plurality of electronic control units 710 or may communicate with a server 810 using an antenna (not shown) and RF communication.

Further, the CCU 760 may communicate with the server 810 via wireless communication. In this regard, the wireless communication between the CCU 760 and the server 810 may be performed using a Wi-Fi module or a WiBro (Wireless broadband) module or based on various wireless communication schemes including GSM (global System for Mobile Communication), CDMA (Code Division Multiple Access), WCDMA (Wideband Code Division Multiple Access), UMTS (universal mobile telecommunications system), TDMA (Time Division Multiple Access), LTE (Long Term Evolution), or etc.

The image sensor as described above may act as a kind of an optical sensor. Thus, the ideas according to the embodiments as described above may be applied not only to the image sensor but also to another type of a sensor that detects an amount of incident light using semiconductor, a fingerprint sensor, a distance measurement sensor, etc.

In concluding the detailed description, those skilled in the art will appreciate that many variations and modifications may be made to the preferred embodiments without substantially departing from the principles of the present invention. Therefore, the disclosed preferred embodiments of the invention are used in a generic and descriptive sense only and not for purposes of limitation.

1. An image sensor comprising:
a plurality of pixels,
wherein each pixel of the plurality of pixels comprises:
a first sub-pixel comprising a first photoelectric conversion area, a first floating diffusion area, and a first transfer transistor configured to transfer charges accumulated in the first photoelectric conversion area to the first floating diffusion area; and
a second sub-pixel disposed adjacent to the first sub-pixel and comprising a second photoelectric conversion area, a second floating diffusion area and a second transfer transistor configured to transfer charges accumulated in the second photoelectric conversion area to the second floating diffusion area,
wherein the first transfer transistor comprises a first transfer gate,
wherein the second transfer transistor comprises a second transfer gate, and
wherein the second transfer gate comprises a vertical multi-gate.

2. The image sensor of claim 1, further comprising a substrate in which the first photoelectric conversion area and the second photoelectric conversion area are disposed,
wherein, in a plan view, an area of the first photoelectric conversion area is larger than an area of the second photoelectric conversion area.

3. The image sensor of claim 2, wherein the first photoelectric conversion area comprises a first maximum impurity concentration area at a first depth from a face of the substrate,
wherein the second photoelectric conversion area comprises a second maximum impurity concentration area at a second depth from the face of the substrate, and
wherein the first depth is smaller than the second depth.

4. The image sensor of claim 3, wherein a gate type of the first transfer gate is different from a gate type of the second transfer gate.

5. The image sensor of claim 4, wherein the first transfer gate is a horizontal gate.

6. The image sensor of claim 4, wherein the first transfer gate is a single gate.

7. The image sensor of claim 3, wherein the second transfer gate comprises a first sub-gate and a second sub-gate,
wherein the first sub-gate faces the second sub-gate, and
wherein the first sub-gate is spaced apart from the second sub-gate.

8. The image sensor of claim 7, wherein, in the plan view, the second maximum impurity concentration area is positioned between the first sub-gate and the second sub-gate in the plan view.

9. The image sensor of claim 2, wherein the first photoelectric conversion area comprises a first maximum impurity concentration area having a first maximum electric potential,
wherein the second photoelectric conversion area comprises a second maximum impurity concentration area having a second maximum electric potential, and
wherein the first maximum electric potential is greater than the second maximum electric potential.

10. The image sensor of claim 9, wherein a width of the first photoelectric conversion area in a horizontal direction is greater than a width of the second photoelectric conversion area in the horizontal direction.

11. The image sensor of claim 1, wherein the first floating diffusion area is spaced apart from the second floating diffusion area.

12. The image sensor of claim 11, further comprising a source follower transistor configured to output the charges accumulated in the first floating diffusion area and the charges accumulated in the second floating diffusion area.

13. An image sensor comprising:
a substrate;
a first photoelectric conversion area disposed in the substrate and having a first width in a horizontal direction;
a second photoelectric conversion area disposed in the substrate and having a second width in the horizontal direction, wherein the second width is smaller than the first width;
a first floating diffusion area disposed in the substrate and spaced apart from a second floating diffusion area disposed in the substrate;
a first transfer transistor at least partially disposed in the substrate or on a face of the substrate, the first transfer transistor being configured to transfer charges accumulated in the first photoelectric conversion area to the first floating diffusion area; and
a second transfer transistor at least partially disposed in the substrate or on the face of the substrate, the second transfer transistor being configured to transfer charges accumulated in the second photoelectric conversion area to the second floating diffusion area,
wherein the first transfer transistor comprises a first transfer gate,
wherein the second transfer transistor comprises a second transfer gate, and
wherein the second transfer gate comprises a vertical multi-gate.

14. The image sensor of claim 13, wherein the first photoelectric conversion area comprises a first maximum impurity concentration area at a first depth from the face of the substrate,
wherein the second photoelectric conversion area comprises a second maximum impurity concentration area at a second depth from the face of the substrate, and
wherein the first depth is smaller than the second depth.

15. The image sensor of claim 14, wherein a gate type of the first transfer gate is different from a gate type of the second transfer gate.

16. The image sensor of claim 15, wherein the first transfer gate comprises a horizontal gate.

17. The image sensor of claim 15, wherein the first transfer gate comprises a single gate.

18. (canceled)

19. (canceled)

20. (canceled)

21. A pixel included in an image sensor, the pixel comprising:
a first sub-pixel comprising:
a first photoelectric conversion area,
a first floating diffusion area, and
a first transfer transistor which comprises a first transfer gate, and is configured to transfer charges accumulated in the first photoelectric conversion area to the first floating diffusion area; and
a second sub-pixel disposed adjacent to the first sub-pixel and comprising:
a second photoelectric conversion area,
a second floating diffusion area, and
a second transfer transistor which comprises a second transfer gate, and is configured to transfer charges accumulated in the second photoelectric conversion area to the second floating diffusion area,
wherein the second transfer gate comprises a vertical multi-gate transistor.

22. The image sensor of claim 21, further comprising a substrate in which the first photoelectric conversion area and the second photoelectric conversion area are disposed,
wherein the first photoelectric conversion area comprises a first maximum impurity concentration area at a first depth from a face of the substrate,
wherein the second photoelectric conversion area comprises a second maximum impurity concentration area at a second depth from the face of the substrate, and
wherein the first depth is smaller than the second depth.

23. The image sensor of claim 22, wherein the second transfer transistor extends further into the substrate than the first transfer transistor.
